(19) United States
(12) Patent Application Publication
(10) Pub. No.: US 2024/0276868 A1
(43) Pub. Date: Aug. 15, 2024

(54) LIGHT EMITTING ELEMENT, METHOD FOR MANUFACTURING THE LIGHT EMITTING ELEMENT, AND DISPLAY DEVICE INCLUDING THE LIGHT EMITTING ELEMENT

(71) Applicant: Samsung Display Co., LTD., Yongin-si (KR)

(72) Inventors: Jungho JO, Yongin-si (KR); CHUL SOON PARK, Yongin-si (KR); YUNKU JUNG, Yongin-si (KR); WON-JUN PARK, Yongin-si (KR); JONGWOO SHIN, Yongin-si (KR)

(21) Appl. No.: 18/532,579

(22) Filed: Dec. 7, 2023

(30) Foreign Application Priority Data
Jan. 26, 2023 (KR) 10-2023-0010216

(51) Int. Cl. H10K 85/30; H10K 50/115; H10K 71/13

(52) U.S. Cl. CPC H10K 85/381; H10K 50/115; H10K 71/135; H10K 50/15; H10K 50/16

(57) ABSTRACT

A light emitting element includes a first electrode, an electron transport region, an emission layer, a hole transport region, and a second electrode, stacked in order. At least one among the electron transport region and the hole transport region includes a metal nanoparticle. The metal nanoparticle includes a core including a metal oxide and a ligand bonded to the core and including at least one among Se and Te. The ligand is derived from a first compound represented by Formula 1 or an ion represented by Formula 2 as described. Accordingly, the light emitting element may be manufactured by an inkjet printing method.

This application claims priority to Korean Patent Application No. 10-2023-0010216, filed on Jan. 26, 2023, and all the benefits accruing therefrom under 35 U.S.C. § 119, the content of which in its entirety is herein incorporated by reference.

### BACKGROUND

The present disclosure herein relates to a light emitting element including a quantum dot, a method for manufacturing the light emitting element, and a display device including the light emitting element.

A light emitting element is an element having conversion properties of electric energy into light energy. A quantum dot light emitting element including a quantum dot in an emission layer in the light emitting element has high color purity and high emission efficiency and is possible to be polychromatic. In the light emitting element, holes move via a hole transport region to the emission layer, and electrons move via an electron transport region to the emission layer. Studies on smooth injection and transport of holes and electrons in a quantum dot light emitting element are being actively conducted for improving light efficiency.

### SUMMARY

An aspect of the present disclosure is to provide a quantum dot light emitting element having excellent light efficiency and a display device including the quantum dot light emitting element.

Another aspect of the present disclosure is to provide a method for manufacturing a light emitting element having excellent manufacturing efficiency.

An embodiment provides a light emitting element including: a first electrode: an electron transport region disposed on the first electrode: an emission layer disposed on the electron transport region and including quantum dots: a hole transport region disposed on the emission layer; and a second electrode disposed on the hole transport region, where at least one among the electron transport region and the hole transport region includes a metal nanoparticle, and the metal nanoparticle includes: a core including a metal oxide; and a ligand bonded to the core, including at least one among Selenium (Se) and Tellurium (Te), and derived from a first compound represented by Formula 1 or an ion represented by Formula 2:

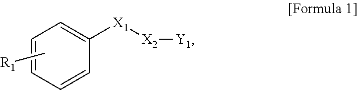

In Formula 1, X₁ is Se or Te, X₂ is a direct linkage, Se, or Te, Y₁ is a hydrogen atom or a substituted or unsubstituted phenyl group, where, if Y₁ is a hydrogen atom, X₂ is a direct linkage, and R₁ is a hydrogen atom, a substituted or unsubstituted amine group of 1 to 10 carbon atoms, a substituted or unsubstituted alkyl group of 1 to 10 carbon atoms, or a substituted or unsubstituted alkoxy group of 1 to 10 carbon atoms.

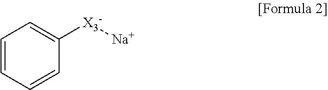

In Formula 2, X₃⁻ is Se⁻ or Te⁻.

In an embodiment, at least one among Se and Te included in the ligand may be bonded to a surface of the core.

In an embodiment, the ligand may include a head part bonded to the surface and including at least one among Se and Te, and a tail part bonded to the head part and including a substituted or unsubstituted phenyl group.

In an embodiment, the first compound may be represented by any one among the compounds in Compound Group 1:

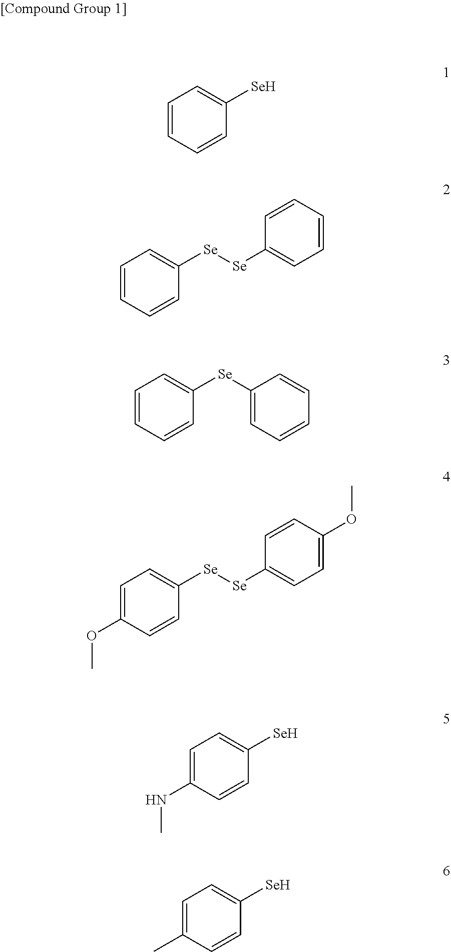

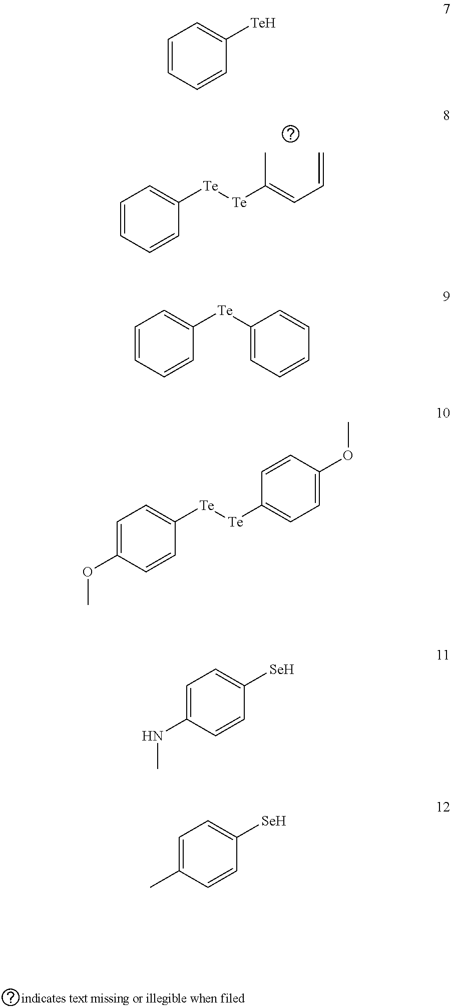

In an embodiment, the metal nanoparticle may further include an auxiliary ligand bonded to the core, and the auxiliary ligand may be derived from a second compound including ethylene glycol thiol.

In an embodiment, the second compound may include at least one among poly(ethylene glycol) 2-merchaptoethyl ether acetic acid and 3-(2-(2-mercaptoethoxy)ethoxy)propanoic acid (thiol-PEG₂-acid).

In an embodiment, the metal oxide may include at least one among SnO, SnO₂, CuGaO₂, Ga₂O₃, Cu₂O, SrCu₂O₂, SrTiO₃, CuAlO₂, Ta₂O₅, NiO, BaSnO₃, and TiO₂, or may be represented by Formula M-1.

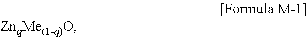

In Formula M-1, “q” is 0 to 0.3, and Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

In an embodiment, a weight of an organic component in the metal nanoparticle may be about 12 wt % to about 30 wt % based on a total weight of the metal nanoparticle.

In an embodiment, the electron transport region may include an electron injection layer disposed on the first electrode, an electron transport layer disposed on the electron injection layer, and a hole blocking layer disposed on the electron transport layer, and at least one among the electron injection layer, the electron transport layer, and the hole blocking layer may include the metal nanoparticle.

In an embodiment, the hole transport region may include an electron blocking layer disposed on the emission layer, a hole transport layer disposed on the electron blocking layer, and a hole injection layer disposed on the hole transport layer, and at least one among the electron blocking layer, the hole transport layer, and the hole injection layer may include the meal nanoparticle.

An embodiment provides a method for manufacturing a light emitting element, including: forming a first electrode on a substrate; forming an electron transport region on the first electrode: providing quantum dots on the electron transport region to form an emission layer: forming a hole transport region on the emission layer; and forming a second electrode on the hole transport region, where at least one among the forming of the electron transport region and the forming of the hole transport region includes providing a composition including a metal nanoparticle, and the metal nanoparticle includes: a core including a metal oxide; and a ligand bonded to the core, including at least one among Se and Te, and derived from a first compound represented by Formula 1 or an ion represented by Formula 2:

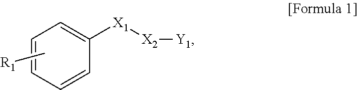

In Formula 1, X₁ is Se or Te, X₂ is a direct linkage, Se, or Te, Y₁ is a hydrogen atom or a substituted or unsubstituted phenyl group, where, if Y₁ is a hydrogen atom, X₂ is a direct linkage, and R₁ is a hydrogen atom, a substituted or unsubstituted amine in group of 1 to 10 carbon atoms, a substituted or unsubstituted alkyl group of 1 to 10 carbon atoms, or a substituted or unsubstituted alkoxy group of 1 to 10 carbon atoms.

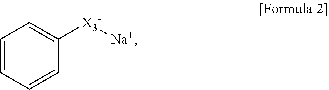

In Formula 2, X₃⁻ is Se⁻ or Te⁻.

In an embodiment, the composition may be provided by an inkjet printing method or a dispensing method.

In an embodiment, the method may further include preparing the metal nanoparticle prior to providing the composition, and the preparing of the metal nanoparticle may include: preparing a preliminary metal nanoparticle including the core and a preliminary ligand bonded to the core; and heating a mixture including the preliminary metal nanoparticle and at least one among the first compound and the ion.

In an embodiment, during the heating of the mixture, the preliminary ligand may be removed, and the ligand may be bonded to the core.

In an embodiment, the mixture may further include at least one among potassium hydroxide, sodium hydroxide, trimethylammonium hydroxide (“TMAM”), and tetramethylammonium hydroxide (“TMAH”).

In an embodiment, at least one among Se and Te, included in the ligand may be bonded to the surface of the core.

In an embodiment, the metal nanoparticle may further include an auxiliary ligand bonded to the core, and the auxiliary ligand may be derived from a second compound including ethylene glycol thiol.

In an embodiment, the metal oxide may include at least one among SnO, SnO₂, CuGaO₂, Ga₂O₃, Cu₂O, SrCu₂O₂, SrTiO₃, CuAlO₂, Ta₂O₅, NiO, BaSnO₃, and TiO₂, or may be represented by Formula M-1:

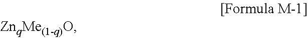

In Formula M-1, “q” is 0 to 0.3, and Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

In an embodiment, a weight of an organic component in the metal nanoparticle may be about 12 wt % to about 30 wt % based on a total weight of the metal nanoparticle.

An embodiment provides a display device including: a circuit layer; and a display element layer including a pixel definition layer disposed on the circuit layer, a pixel opening being defined in the pixel definition layer, and a light emitting element, where the light emitting element includes: a first electrode exposed at the pixel opening: an electron transport region disposed on the first electrode: an emission layer disposed on the electron transport region and including quantum dots; a hole transport region disposed on the emission layer; and a second electrode disposed on the hole transport region, at least one among the electron transport region and the hole transport region includes a metal nanoparticle, and the metal nanoparticle includes: a core including a metal oxide; and a ligand bonded to the core, including at least one among Se and Te, and derived from a first compound represented by Formula 1 or an ion represented by Formula 2:

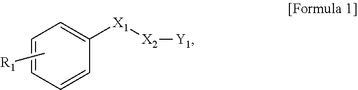

In Formula 1, X₁ is Se or Te, X₂ is a direct linkage, Se, or Te, Y₁ is a hydrogen atom or a substituted or unsubstituted phenyl group, where, if Y₁ is a hydrogen atom, X₂ is a direct linkage, and R₁ is a hydrogen atom, a substituted or unsubstituted amine group of 1 to 10 carbon atoms, a substituted or unsubstituted alkyl group of 1 to 10 carbon atoms, or a substituted or unsubstituted alkoxy group of 1 to 10 carbon atoms.

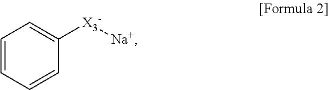

In Formula 2, X₃⁻ is Se⁻ or Te⁻.

In an embodiment, at least one among Se and Te, included in the ligand may be bonded to the surface of the core.

In an embodiment, the metal nanoparticle may further include an auxiliary ligand bonded to the core, and the auxiliary ligand may be derived from a second compound including ethylene glycol thiol.

In an embodiment, the metal oxide may include at least one among SnO, SnO₂, CuGaO₂, Ga₂O₃, Cu₂O, SrCu₂O₂, SrTiO₃, CuAlO₂, Ta₂O₅, NiO, BaSnO₃, and TiO₂, or may be represented by Formula M-1:

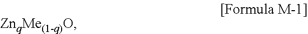

In Formula M-1, “q” is 0 to 0.3, and Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

### BRIEF DESCRIPTION OF THE FIGURES

The accompanying drawings are included to provide a further understanding of the invention and are incorporated in and constitute a part of this specification. The drawings illustrate embodiments of the invention and, together with the description, serve to explain principles of the invention. In the drawings:

FIG. 1 is a perspective view showing a display device of an embodiment;

FIG. 2 is a cross-sectional view showing a part corresponding to line I-I′in FIG. 1;

FIG. 3 is a plan view showing a display device of an embodiment;

FIG. 4 is a cross-sectional view showing part corresponding to line II-II′ in FIG. 3;

FIG. 5A is a cross-sectional view showing a light emitting element according to an embodiment;

FIG. 5B is a cross-sectional view showing a light emitting element according to another embodiment;

FIG. 6A is a diagram showing a metal nanoparticle according to an embodiment;

FIG. 6B is a diagram showing region XX′ in FIG. 6A;

FIG. 6C is a diagram showing a metal nanoparticle according to another embodiment:

FIG. 7 is a flowchart showing a method for manufacturing a light emitting element of an embodiment:

FIG. 8 is a diagram schematically showing a manufacturing step of a light emitting element of an embodiment:

FIG. 9 is a diagram schematically showing a manufacturing step of a light emitting element of an embodiment; and

FIG. 10 is a diagram showing region AA′ in FIG. 9.

### DETAILED DESCRIPTION

The invention may have various modifications and may be embodied in different forms, and example embodiments will be explained in detail with reference to the accompany drawings. The invention may, however, be embodied in different forms and should not be construed as limited to the embodiments set forth herein. Rather, all modifications, equivalents, and substituents which are included in the spirit and technical scope of the invention should be included in the invention.

In the description, when an element (or a region, a layer, a part, etc.) is referred to as being “on”, “connected with” or “combined with” another element, it can be directly disposed on/connected with/bonded to the other element, or intervening third elements may also be disposed.

Like reference numerals refer to like elements throughout. In the drawings, the thicknesses, ratios, and dimensions of elements are exaggerated for effective explanation of technical contents. The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” “and/or” may include one or more combinations that may define relevant elements.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value.

It will be understood that, although the terms “first”, “second”, etc. may be used herein to describe various elements, these elements should not be limited by these terms. These terms are only used to distinguish one element from another element. For example, a first element could be termed a second element without departing from the scope of the present invention. Similarly, a second element could be termed a first element. As used herein, the singular forms are intended to include the plural forms as well, unless the context clearly indicates otherwise.

In addition, the terms “below”, “beneath”, “on” and “above” are used for explaining the relation of elements shown in the drawings. The terms are relative concept and are explained based on the direction shown in the drawing.

It will be further understood that the terms “comprises” or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

Unless otherwise defined, all terms (including technical and scientific terms) used herein have the same meaning as commonly understood by one of ordinary skill in the art to which this invention belongs. In addition, it will be further understood that terms, such as those defined in commonly used dictionaries, should be interpreted as having a meaning that is consistent with their meaning in the context of the relevant art and will not be interpreted in an idealized or overly formal sense unless expressly defined so herein.

In the description, the term “substituted or unsubstituted” corresponds to substituted or unsubstituted with at least one substituent selected from the group consisting of a deuterium atom, a halogen atom, a cyano group, a nitro group, an amine group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In addition, each of the exemplified substituents may be substituted or unsubstituted. For example, a biphenyl group may be interpreted as an aryl group or a phenyl group substituted with a phenyl group.

In the description, an alkyl group may be a linear, or branched type. The carbon number of the alkyl group may be 1 to 60, 1 to 50, 1 to 30, 1 to 20, 1 to 10, or 1 to 6. Examples of the alkyl group may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, 1-methylpentyl, 3-methylpentyl, 2-ethylpentyl, 4-methyl-2-pentyl, n-hexyl, 1-methylhexyl, 2-ethylhexyl, 2-butylhexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, an alkoxy group may mean the above-defined alkyl group which is combined with an oxygen atom. The alkoxy group may be a linear, branched or cyclic chain. The carbon number of the alkoxy group is not specifically limited but may be, for example, 1 to 30, 1 to 20, 1 to 10, or 1 to 5. Examples of the alkoxy group may include methoxy, ethoxy, n-propoxy, isopropoxy, butoxy, pentyloxy, hexyloxy, octyloxy, nonyloxy, decyloxy, etc. However, an embodiment of the invention is not limited thereto.

In the description, the carbon number of an amine group is not specifically limited, but may be 1 to 30, 1 to 20, or 1 to 10. The amine group may include an alkyl amine group and an aryl amine group. Examples of the amine group include a methylamine group, a dimethylamine group, a phenylamine group, a diphenylamine group, a naphthylamine group, a 9-methyl-anthracenylamine group, etc., without limitation.

In the description, a direct linkage may mean a single bond.

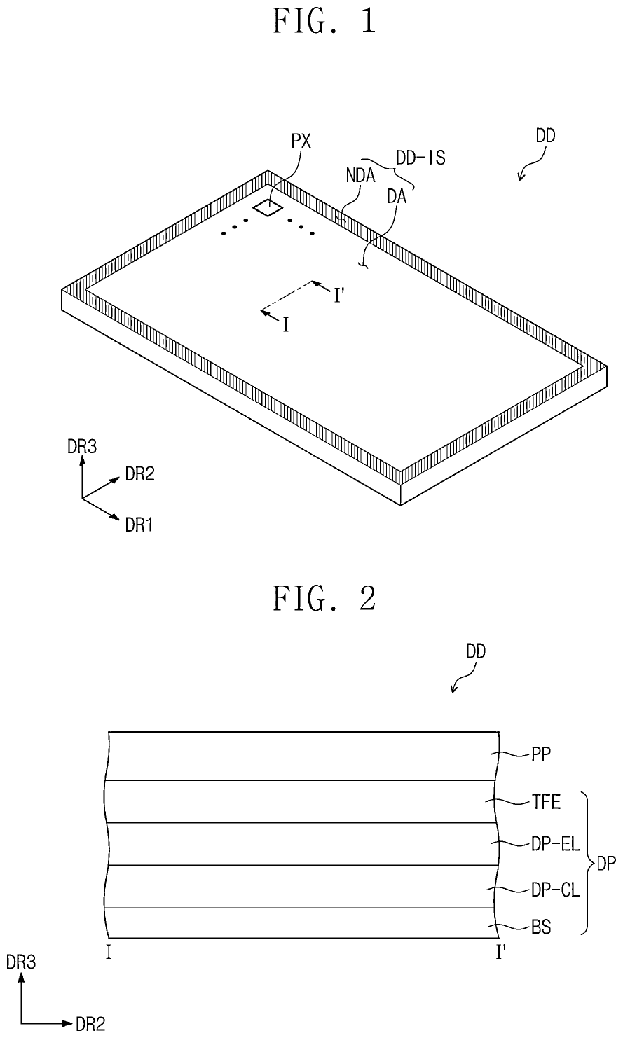

Hereinafter, a light emitting element according to an embodiment of the invention and a display device including the light emitting element will be explained referring to the drawings. FIG. 1 is a perspective view showing a display device of an embodiment.

Referring to FIG. 1, the display device DD of an embodiment may be a device activated by electrical signals. For example, the display device DD may be a large-sized device such as a television, a monitor and an external billboard. In addition, the display device DD may be small- and medium-sized devices such as a personal computer, a laptop computer, a personal digital terminal, a car navigation unit, a game console, a smart phone, a tablet and a camera. In addition, these are suggested only as examples, and the display device DD may be employed as other electronic devices unless deviated from the invention.

The display device DD may display images (or videos) through a display surface DD-IS. The display surface DD-IS may be parallel to a plane defined by a first direction DR1 and a second direction DR2. The display surface DD-IS may include a display area DA and a non-display area NDA.

In the display area DA, a pixel PX may be disposed, and in the non-display area NDA, the pixel PX may not be disposed. The non-display area NDA may be defined along the edge of the display surface DD-IS. The non-display area NDA may surround the display area DA. However, an embodiment of the invention is not limited thereto, and the non-display area NDA may be omitted, or the non-display area NDA may be disposed only at one side of the display area DA in another embodiment.

In FIG. 1, a display device DD provided with a planar display surface DD-IS is shown, but an embodiment of the invention is not limited thereto. In another embodiment, the display device DD may include a curve-type display surface or a three-dimensional display surface. The three-dimensional display surface may include multiple display areas indicating other directions from each other.

In FIG. 1 and the drawings below, a first directional axis DTI to a third directional axis DR3 are shown, and the directions indicated by the first to third directional axes DR1, DR2 and DR3, explained in the description have relative concept and may be converted to other directions. In addition, the directions indicated by the first to third directional axes DR1, DR2 and DR3 may be explained as a first to third directions, and the same reference symbol may be used. In the description, the first directional axis DR1 and the second directional axis DR2 may be orthogonal to each other, and the third directional axis DR3 may be the normal direction to a plane defined by the first directional axis DR1 and the second directional axis DR2. In the description, a “plane” means a plane defined by the first directional axis DR1 and the second directional axis DR2, a “cross-section” may mean a surface perpendicular to the plane defined by the first directional axis DR1 and the second directional axis DR2 and parallel to the third directional axis DR3. The thickness direction of the display device DD may be a direction parallel to the third direction DR3 that is a normal direction to the plane defined by the first direction DR1 and the second direction DR2.

In the description, the top surface (or front surface) and bottom surface (or rear surface) of the members constituting the display deice DD may be defined based on the third direction DR3. More particularly, for one element, a surface relatively adjacent to the display surface DD-IS among two facing surfaces based on the third direction DR3 may be defined as the front surface (or top surface), and a surface relatively separated apart from the display surface DD-IS may be defined as the rear surface (or bottom surface). In addition, in the description, an upper part (or upper side) or a lower part (or lower side) may be defined based on the third direction DR3, and the upper part (or upper side) may be defined as a direction close to the display surface DD-IS, and the lower part (lower side) may be defined as a direction away from the display surface DD-IS.

In the description, one element is “disposed directly/formed directly on” another element, may mean that there are no third elements between the one element and another element. That is, one element is “disposed directly/formed directly on” another element, may mean that the one element and another element make “contact” from each other.

FIG. 2 is a cross-sectional view showing a part corresponding to line I-I′. FIG. 2 may be the cross-sectional view of a display device according to an embodiment.

The display device DD may include a display panel DP and an optical layer PP disposed on the display panel DP. The display panel DP may include a base layer BS, a circuit layer DP-CL disposed on the base layer BS, a display element layer DP-EL disposed on the circuit layer DP-CL, and an encapsulating layer TFE disposed on the display element layer DP-EL.

The display panel DP may be an element substantially producing images. The display panel DP may be an emission-type display panel. In an embodiment, for example, the display panel DP may be a quantum dot emission display panel including a quantum dot light emitting element.

The base layer BS may be a member providing a base surface for disposing the circuit layer DP-CL. The base layer BS may be a rigid substrate or a flexible substrate of which bending, folding, rolling, or the like is possible. The base layer BS may be a glass substrate, a metal substrate or a polymer substrate. However, an embodiment of the invention is not limited thereto, and the base layer BS may be an inorganic layer, an organic layer or a composite material layer in another embodiment.

The circuit layer DP-CL may be disposed on the base layer BS. The circuit layer DP-CL may include an insulating layer, a semiconductor pattern, a conductive pattern, and a signal line. After forming an insulating layer, a semiconductor layer and a conductive layer on the base layer BS by a method of coating, depositing, or the like, the insulating layer, semiconductor layer and conductive layer may be selectively patterned through multiple photolithography processes. After that, a semiconductor pattern, a conductive pattern, and a signal line, included in the circuit layer DP-CL may be formed.

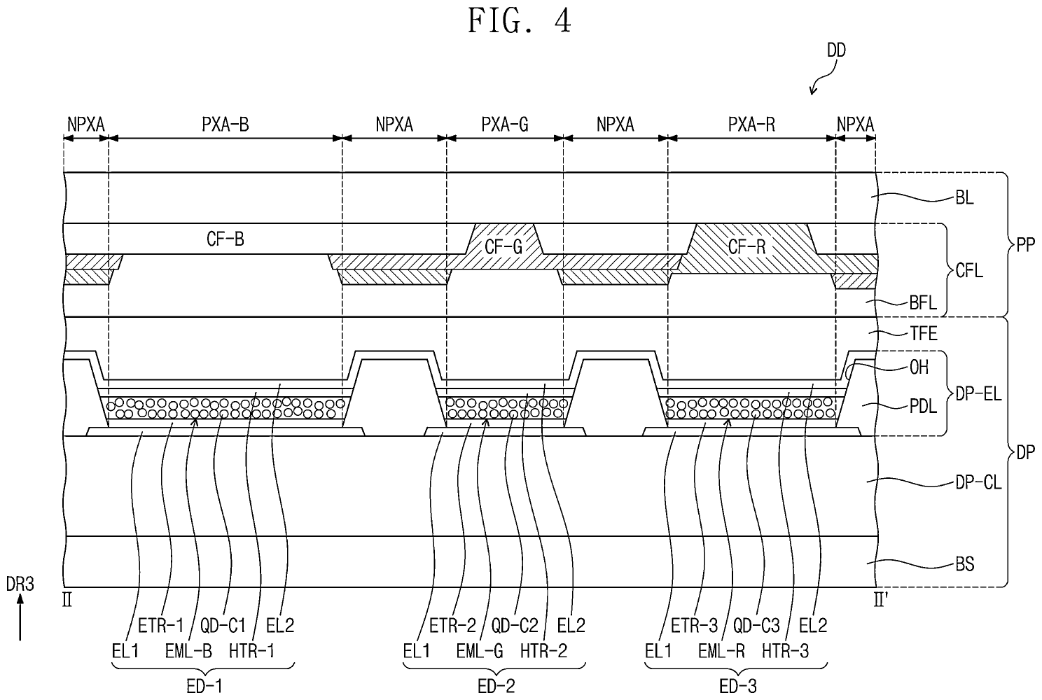

The display element layer DP-EL may be disposed on the circuit layer DP-CL. The display element layer DP-EL may include a pixel definition layer PDL, and first to third light emitting elements ED-1, ED-2 and ED-3 (FIG. 4), which will be explained later. In an embodiment, for example, the display element layer DP-EL may include an organic light emitting material, an inorganic light emitting material, an organic-inorganic light emitting material, a quantum dot, a quantum rod, a micro LED, or a nano LED. More particularly, the display element layer DP-EL may include a quantum dot.

The encapsulating layer TFE may protect the display element layer DP-EL from foreign materials such as moisture, oxygen and dust particles. The encapsulating layer TFE may include at least one inorganic layer. The encapsulating layer may include a stacked structure of an inorganic layer, an organic layer and an inorganic layer in order.

The optical layer PP may be disposed on the display panel DP and may control reflected light at the display panel DP by external light. The optical layer PP may include, for example, a polarization layer or a color filter layer. In another embodiment, different from the drawings, the optical layer PP may be omitted.

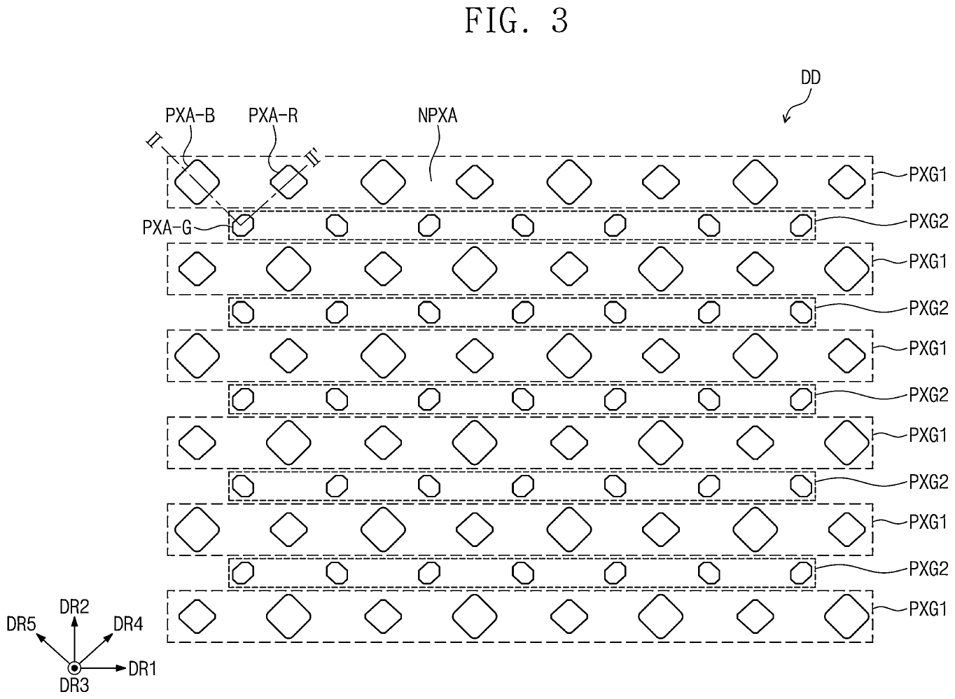

FIG. 3 is a plan view showing a display device of an embodiment. FIG. 4 is a cross-sectional view showing a part corresponding to line II-II′in FIG. 3. FIG. 3 may be a cross-sectional view showing a display device of an embodiment.

Referring to FIG. 3 and FIG. 4, a display device DD may include a peripheral area NPXA and luminous areas PXA-R, PXA-G and PXA-B. The luminous areas PXA-R, PXA-G and PXA-B may be areas for emitting light produced from the light emitting elements ED-1, ED-2 and ED-3, respectively. The areas of the luminous areas PXA-R, PXA-G and PXA-B may be different from each other, and in this case, the area may mean an area on a plane.

The luminous areas PXA-R, PXA-G and PXA-B may be divided into multiple groups according to the color of light produced from the light emitting elements ED-1, ED-2 and ED-3. In FIG. 3 and FIG. 4, three luminous areas PXA-R. PXA-G and PXA-B for emitting red light, green light and blue light are illustrated as an embodiment. For example, the display device DD of an embodiment may include a red luminous area PXA-R, a green luminous area PXA-G and a blue luminous area PXA-B, which are divided from each other.

The display panel DP may include multiple light emitting elements ED-1, ED-2 and ED-3 for emitting light having different wavelength regions from each other. The multiple light emitting elements ED-1, ED-2 and ED-3 may emit light of different colors from each other. For example, the display panel DP may include a first light emitting element ED-1 for emitting red light, a second light emitting element ED-2 for emitting green light, and a third light emitting element ED-3 for emitting blue light. However, an embodiment of the invention is not limited thereto, and the first to third light emitting elements ED-1, ED-2 and ED-3 may emit light in the same wavelength region, or at least one thereof may emit light in a different wavelength region in another embodiment.

In the display device DD of an embodiment, shown in FIG. 3 and FIG. 4, the luminous areas PXA-R, PXA-G and PXA-B may have different areas according to the color emitted from the emission layers EML-B, EML-G and EML-R of the light emitting elements ED-1, ED-2 and ED-3. The blue luminous area PXA-B of the first light emitting element ED-1, for emitting blue light, may have the largest area, the green luminous area PXA-G of the second light emitting element ED-2, for emitting green light, may have the smallest area. However, an embodiment of the invention is not limited thereto, and the luminous areas PXA-R, PXA-G and PXA-B may emit light of a color different from red light, green light and blue light in another embodiment. Otherwise, the luminous areas PXA-R, PXA-G and PXA-B may have the same area, or the luminous areas PXA-R, PXA-G and PXA-B may be provided with an area ratio different from that shown in FIG. 3.

Each of the luminous areas PXA-R, PXA-G and PXA-B may be an area divided by a pixel definition layer PDL. The peripheral areas NPXA may be areas between neighboring luminous areas PXA-R, PXA-G and PXA-B and may be an area corresponding to the pixel definition layer PDL. Each of the luminous areas PXA-R, PXA-G and PXA-B may correspond to a pixel.

The pixel definition layer PDL may define the luminous areas PXA-R, PXA-G and PXA-B. The luminous areas PXA-R, PXA-G and PXA-B and the peripheral area NPXA may be divided by the pixel definition layer PDL.

The blue luminous areas PXA-B and the red luminous areas PXA-R may be arranged by turns along a first directional axis DR1 to form a first group PXG1. The green luminous areas PXA-G may be arranged along the first directional axis DR1 to form a second group PXG2. The first group PXG1 may be separately disposed in the second directional axis DR2 with respect to the second group PXG2. Multiple first groups PXG1 and multiple second groups PXG2 may be provided. The first groups PXG1 and the second groups PXG2 may be arranged by turns in the second directional axis DR2.

One red luminous area PXA-R may be separately disposed in a fourth directional axis DR4 from one green luminous area PXA-G. One blue luminous area PXA-B may be separately disposed in a fifth directional axis DR5 from one green luminous area PXA-G. The fourth directional axis DR4 may be a direction between the first directional axis DR1 and the second directional axis DR2. The fifth directional axis DR5 may be a direction crossing the fourth directional axis DR4 and tilted with respect to the second directional axis DR2.

The arrangement structure of the luminous areas PXA-R, PXA-G and PXA-B is not limited to the arrangement structure shown in FIG. 3. For another example, in the luminous areas PXA-R, PXA-G and PXA-B, the red luminous area PXA-R, the green luminous area PXA-G and the blue luminous area PXA-B may be arranged by turns along the first directional axis DR1. In addition, on a plane, the shapes of the luminous areas PXA-R, PXA-G and PXA-B are not limited to those shown in the drawing, and may be defined into shapes different from those shown in the drawing.

In FIG. 4, the base layer BS may include a single layer or a multiplayer structure. In an embodiment, for example, the base layer BS may include a first synthetic resin layer, an interlayer of a multilayer or a single layer structure, and a second synthetic resin layer. The interlayer may be referred to as a base barrier layer. The interlayer may include a silicon oxide (SiOx) layer and an amorphous silicon (a-Si) layer disposed on the silicon oxide layer, but an embodiment of the invention is not specifically limited thereto. For another example, the interlayer may include at least one among a silicon oxide layer, a silicon nitride layer, a silicon oxynitride layer, and an amorphous silicon layer.

Each of the first and second synthetic resin layers may include a polyimide-based resin. In addition, each of the first and second synthetic resin layers may include at least one among an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin and a perylene-based resin. In the description, “˜˜”-based resin means a resin including the functional group of “˜˜”.

The circuit layer DP-CL may be disposed on the base layer BS, and the circuit layer DP-CL may include multiple transistors (not shown). Each of the transistors (not shown) may include a control electrode, an input electrode, and an output electrode. In an embodiment, for example, the circuit layer DP-CL may include a switching transistor and a driving transistor for driving the light emitting elements ED-1, ED-2 and ED-3 of the display element layer DP-EL.

The display element layer DP-EL may include the pixel definition layer PDL and the first to third light emitting elements ED-1, ED-2 and ED-3. In the pixel definition layer PDL, a pixel opening OH may be defined. The pixel definition layer PDL may divide the first to third light emitting elements ED-1, ED-2 and ED-3. The emission layers EML-R, EML-G and EML-B of the first to third light emitting elements ED-1, ED-2 and ED-3 may be disposed and divided in the pixel opening OH defined in the pixel definition layer PDL.

The pixel definition layer PDL may be formed using a polymer resin. In an embodiment, for example, the pixel definition layer PDL may be formed by including a polyacrylate-based resin or a polyimide-based resin. In addition, the pixel definition layer PDL may be formed by further including an inorganic material in addition to the polymer resin. In another embodiment, the pixel definition layer PDL may be formed by including a light absorption material or formed by including a black pigment or a black dye. The pixel definition layer PDL formed by including a black pigment or a black dye may accomplish a black pixel definition layer. Carbon black, or the like may be used as the black pigment or the black dye during forming the pixel definition layer PDL, but an embodiment of the invention is not limited thereto.

In addition, the pixel definition layer PDL may be formed using an inorganic material. In an embodiment, for example, the pixel definition layer PDL may be formed using an inorganic material including silicon nitride (SiNx), silicon oxide (SiOx), silicon oxynitride (SiOxNy), or the like.

The light emitting elements ED-1, ED-2 and ED-3 may include a first electrode EL1, hole transport regions HTR-1, HTR-2 and HTR-3 disposed on the first electrode EL1, emission layers EML-B, EML-G and EML-R disposed on the hole transport regions HTR-1, HTR-2 and HTR-3, electron transport regions ETR-1, ETR-2 and ETR-3 disposed on the emission layers EML-B, EML-G and EML-R, and a second electrode EL2 disposed on the electron transport regions ETR-1, ETR-2 and ETR-3.

The first electrode EL1 may be exposed at the pixel opening OH of the pixel definition layer PDL. The first electrode EL1 has conductivity. The first electrode EL1 may be formed using a metal material, a metal alloy or a conductive compound. The first electrode EL1 may be a cathode or an anode. However, an embodiment of the invention is not limited thereto. In addition, the first electrode EL1 may be a pixel electrode. The first electrode EL1 may be a transmissive electrode, a transflective electrode, or a reflective electrode. The first electrode EL1 may include at least one selected among Ag, Mg, Cu, Al, Pt, Pd, Au, Ni, Nd, Ir, Cr, Li, Ca, LiF, Mo, Ti, W, In, Sn and Zn, compounds of two or more selected therefrom, mixtures of two or more selected therefrom, or oxides thereof.

If the first electrode EL1 is the transmissive electrode, the first electrode EL1 may include a transparent metal oxide, for example, indium tin oxide (“ITO”), indium zinc oxide (“IZO”), zinc oxide (ZnO), indium tin zinc oxide (“ITZO”), or the like. If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, compounds thereof, or mixtures thereof (for example, a mixture of Ag and Mg). Also, the first electrode EL1 may have a structure including multiple layers including a reflective layer or a transflective layer formed using the above materials, and a transmissive conductive layer formed using ITO, IZO, ZnO, or ITZO. In an embodiment, for example, the first electrode EL1 may have a three-layer structure of ITO/Ag/ITO, without limitation. In addition, the first electrode EL1 may include the above-described metal materials, combinations of two or more metal materials selected from the above-described metal materials, or oxides of the above-described metal materials. However, an embodiment of the invention is not limited thereto. The thickness of the first electrode EL1 may be from about 700 angstrom (A) to about 10,000 Å. For example, the thickness of the first electrode EL 1 may be from about 1,000 Å to about 3,000 Å.

The second electrode EL2 may be a common electrode. The second electrode EL2 may be an anode or a cathode, but an embodiment of the invention is not limited thereto. In another embodiment, for example, if the first electrode EL 1 is an anode, the second cathode EL2 may be a cathode, and if the first electrode EL1 is a cathode, the second electrode EL2 may be an anode. The second electrode EL2 may include at least one selected among Ag, Mg, Cu, Al, Pt, Pd, Au, Ni, Nd, Ir, Cr, Li, Ca, LiF, Mo, Ti, W, In, Sn, and Zn, compounds of two or more selected therefrom, mixtures of two or more selected therefrom, or oxides thereof.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb, W, compounds including thereof, or mixtures thereof (for example, AgMg, AgYb, or MgYb). Otherwise, the second electrode EL2 may have a multilayered structure including a reflective layer or a transflective layer formed using the above-described materials and a transparent conductive layer formed using ITO, IZO, ZnO, ITZO, etc. In an embodiment, for example, the second electrode EL2 may include the aforementioned metal materials, combinations of two or more metal materials selected from the aforementioned metal materials, or oxides of the aforementioned metal materials.

Though not shown, the second electrode EL2 may be connected with an auxiliary electrode. If the second electrode EL2 is connected with the auxiliary electrode, the resistance of the second electrode EL2 may decrease.

Between the first electrode EL1 and the second electrode EL2, emission layers EML-B, EML-G and EML-R may be disposed. The first light emitting element ED-1 may include the first emission layer EML-B, the second light emitting element ED-2 may include the second emission layer EML-G, and the third light emitting element ED-3 may include the third emission layer EML-R. The first emission layer EML-B may include a first quantum dot QD-C1. The second emission layer EML-G may include a second quantum dot QD-C2. The third emission layer EML-R may include the third quantum dot QD-C3.

The quantum dots QD-C1, QD-C2 and QD-C3 included in the emission layers EML-B, EML-G and EML-R may be stacked to form layers. In FIG. 4, quantum dots QD-C1, QD-C2 and QD-C3 having a circular shape cross-sections are arranged to form roughly two layers as an embodiment, but an embodiment of the invention is not limited thereto. For another example, according to the thicknesses of the emission layers EML-B, EML-G and EML-R, the shapes of the quantum dots QD-C1, QD-C2 and QD-C3 included in the emission layers EML-B, EML-G and EML-R, and the average diameters of the quantum dots QD-C1, QD-C 2 and QD-C3, the arrangement of the quantum dots QD-C1, QD-C2 and QD-C3 may be changed. Particularly, the quantum dots QD-C1, QD-C2 and QD-C3 in the emission layers EML-B, EML-G and EML-R may be arranged in the neighborhood to form one layer, or arranged to form a multilayer of two layers, three layers, or the like.

The first quantum dot QD-C1 of the first light emitting element ED-1 may emit blue light. The second quantum dot QD-C2 of the second light emitting element ED-2 may emit green light. The third quantum dot QD-C3 of the third light emitting element ED-3 may emit red light. Each of the quantum dots QD-C1, QD-C2 and QD-C3 may include a core (not shown) and a shell (not shown) surrounding the core. Accordingly, each of the quantum dots QD-C1, QD-C2 and QD-C3 may include a core-shell structure. The cores of the quantum dots QD-C1, QD-C2 and QD-C3 may include different materials from each other. Differently, the cores of the quantum dots QD-C1, QD-C2 and QD-C3 may include the same material. Otherwise, two cores selected from the cores of the quantum dots QD-C 1, QD-C2 and QD-C3 may include the same material, and the remaining one core may include a different material.

In FIG. 4, the diameters of the first to third quantum dots QD-C1, QD-C 2 and QD-C3 are shown similar, but an embodiment of the invention is not limited thereto. The diameters of the first to third quantum dots QD-C1, QD-C2 and QD-C 3 may be different from each other in another embodiment. For example, the first quantum dot QD-C1 of the first light emitting element ED-1, for emitting light of a relatively short wavelength region may have a relatively smaller average diameter when compared to the second quantum dot QD-C2 of the second light emitting element ED-2 and the third quantum dot QD-C3 of the third light emitting element ED-3. The average diameter corresponds to an arithmetic average value of the particle diameters of multiple quantum dots. The particle diameter of the quantum dots may be an average value of the widths on the cross-sections of the quantum dot particles.

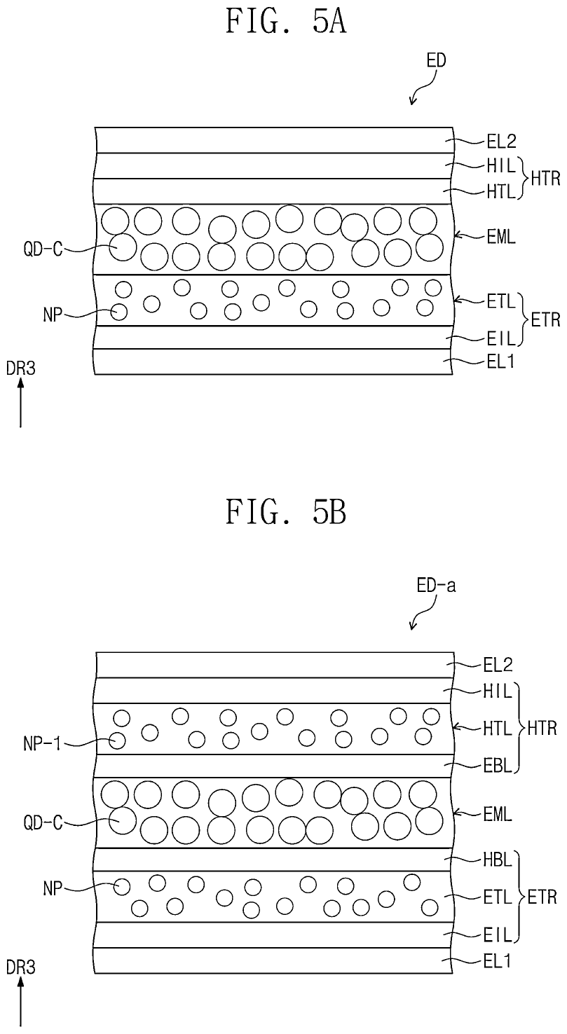

Between the first electrode EL1 and the emission layers EML-B, EML-G and EML-R, electron transport regions ETR-1, ETR-2 and ETR-3 may be disposed. Between the emission layers EML-B, EML-G and EML-R and the second electrode EL2, hole transport regions HTR-1, HTR-2 and HTR-3 may be disposed. In an embodiment, at least one among the electron transport regions ETR-1, ETR-2 and ETR-3 and the hole transport regions HTR-1, HTR-2 and HTR-3 may include metal nanoparticles NP (FIG. 5A) which will be explained later. In an embodiment, the metal nanoparticle NP (FIG. 5A) may include a ligand LD and a ligand LD-bonded core MC. The ligand LD includes Selenium (Se) bonded to a phenyl group and/or Tellurium (Te) bonded to a phenyl group, and the metal nanoparticle NP (FIG. 5A) including the ligand LD may show excellent stability with the passage of time and improve the light efficiency of the light emitting elements ED-1, ED-2 and ED-3. The metal nanoparticle NP (FIG. 5A) will be explained in more detail later.

The hole transport regions HTR-1, HTR-2 and HTR-3 of the first to third light emitting elements ED-1, ED-2 and ED-3 may be disposed in the pixel opening OH to be divided. The first light emitting element ED-1 may include the first hole transport region HTR-1, the second light emitting element ED-2 may include the second hole transport region HTR-2, and the third light emitting element ED-3 may include the third hole transport region HTR-3.

Each of the hole transport regions HTR-1, HTR-2 and HTR-3 may have a single layer formed using a single material, a single layer formed using multiple different materials, or a multilayer structure including multiple layers formed using multiple different materials. The thicknesses of the first to third hole transport regions HTR-1, HTR-2 and HTR-3 may be, for example, about 50 Å to about 15,000 Å. The thicknesses of the first to third hole transport regions HTR-1, HTR-2 and HTR-3 may be, for example, about 100 Å to about 10,000 Å, for example, about 100 Å to about 5,000 Å.

The first to third hole transport regions HTR-1, HTR-2 and HTR-3 may further include a known hole injection material and/or a known hole transport material. In an embodiment, for example, the first to third hole transport regions HTR-1, HTR-2 and HTR-3 may include a phthalocyanine compound such as copper phthalocyanine, N1,N1′-([1,1′-biphenyl]-4,4′-diyl)bis(N1-phenyl-N4,N4-di-m-tolylbenzene-1,4-diamine) (“DNTPD”), 4,4′,4″-[tris(3-methylphenyl)phenylamino] triphenylamine (“m-MTDATA”), 4,4′,4″-tris(N,N-diphenylamino)triphenylamine (“TDATA”), 4,4′,4″-tris[N(2-naphthyl)-N-phenylamino]-triphenylamine (2-TNATA), poly(3,4-ethylenedioxythiophene)/poly(4-styrenesulfonate) (“PEDOT/PSS”), polyaniline/dodecylbenzenesulfonic acid (“PANI/DBSA”), polyaniline/camphor sulfonic acid (“PANI/CSA”), polyaniline/poly(4-styrenesulfonate) (“PANI/PSS”), N,N′-di(1-naphthalene-1-yl)-N,N′-diphenyl-benzidine (“NPB”), triphenylamine-containing polyetherketone (“TPAPEK”), 4-isopropyl-4′-methyldipheny liodonium [tetrakis(pentafluorophenyl)borate], and dipyrazino[2,3-f:2′,3′-h] quinoxaline-2,3,6,7,10,11-hexacarbonitrile (“HATCN”).

In addition, the first to third hole transport regions HTR-1, HTR-2 and HTR-3 may include carbazole derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (“TPD”), triphenylamine-based derivatives such as 4,4′,4″-tris(N-carbazolyl)triphenylamine (“TCTA”), N,N′-di(naphthalene-1-yl)-N,N′-diplienyl-benzidine (“NPB”), 4,4′-cyclohexylidene bis[N,N-bis(4-methylphenyl)benzeneamine] (“TAPC”), 4,4′-bis[N,N′-(3-tolyl)amino]-3,3′-dimethylbiphenyl (“HMTPD”), 9-(4-tert-butylphenyl)-3,6-bis(triphenylsilyl)-9H-carbazole (CzSi), 9-phenyl-9H-3,9′-bicarbazole (“CCP”), 1,3-bis(N-carbazolyl)benzene (mCP), or 1,3-bis(1,8-dimethyl-9H-carbazol-9-yl)benzene (mDCP), etc.

The electron transport regions ETR-1, ETR-2 and ETR-3 of the first to third light emitting elements ED-1, ED-2 and ED-3 may be disposed and divided in the pixel opening OH. The first light emitting element ED-1 may include the first electron transport region ETR-1, the second light emitting element ED-2 may include the second electron transport region ETR-2, and the third light emitting element ED-3 may include the third electron transport region ETR-3.

Each of the first to third electron transport regions ETR-1, ETR-2 and ETR-3 may have a single layer formed using a single material, a single layer formed using multiple different materials, or a multilayer structure having multiple layers formed using different materials. The thicknesses of the first to third electron transport regions ETR-1, ETR-2 and ETR-3 may be, for example, about 1000 Å to about 1500 Å.

The first to third electron transport regions ETR-1, ETR-2 and ETR-3 may further include a known electron injection material and/or a known electron transport material. In an embodiment, for example, the electron transport region ETR may include an anthracene-based compound. Otherwise, the first to third electron transport regions ETR-1, ETR-2 and ETR-3 may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazol-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (“BCP”), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (“ADN”), 1,3-bis[3,5-di(pyridin-3-yl)phenyl]benzene (BmPyPhB), and mixtures thereof. Otherwise, the electron transport region ETR may include 2,9-dimethyl-4,7-diphenyl-1,10-phenanthroline (BCP), diphenyl(4-(triphenylsilyl)phenyl)phosphine oxide (“TSPO1”), 4,7-diphenyl-1,10-phenanthroline (Bphen), or the like.

The encapsulating layer TFE may include at least one inorganic layer (hereinafter, encapsulating inorganic layer). In addition, the encapsulating layer TFE may include at least one organic layer (hereinafter, encapsulating organic layer) and at least one encapsulating inorganic layer.

The encapsulating inorganic layer may protect the display element layer DP-EL from moisture/oxygen, and the encapsulating organic layer may protect the display element layer DP-EL from foreign materials such as dust particles. The encapsulating inorganic layer may include silicon nitride, silicon oxy nitride, silicon oxide, titanium oxide, or aluminum oxide, without specific limitation. The encapsulating organic layer may include an acrylic compound, an epoxy-based compound, etc. The encapsulating organic layer may include a photopolymerizable organic material, without specific limitation.

An optical layer PP may include a base substrate BL and a color filter layer CFL. The base substrate BL may be a member providing a base surface where the color filter layer CFL is disposed. The base substrate BL may be a glass substrate, a metal substrate, a plastic substrate, or the like. However, an embodiment of the invention is not limited thereto, but the base substrate BL may be an inorganic layer, an organic layer or a composite material layer in another embodiment.

The color filter layer CFL may include first to third filters CF-B, CF-G and CF-R. The first to third color filters CF-B, CF-G and CF-R may be disposed correspondingly to the first to third light emitting elements ED-1, ED-2 and ED-3, respectively. For example, the first filter CF-B may be a blue filter, the second filter CF-G may be a green filter, and the third filter CF-R may be a red filter. The first to third filters CF-B, CF-G and CF-R may be disposed corresponding to the first to third pixel areas PXA-R, PXA-B and PXA-G, respectively.

Each of the first to third filters CF-B, CF-G and CF-R may include a photosensitive polymer resin and a pigment or dye. The first filter CF-B may include a blue pigment or a blue dye, the second filter CF-G may include a green pigment or a green dye, and the third filter CF-R may include a red pigment or a red dye. However, an embodiment of the invention is not limited thereto, and the first filter CF-B may not include the pigment or dye in another embodiment. The first filter CF-B may include a photosensitive polymer resin and not include a pigment or dye. The first filter CF-B may be transparent. The first filter CF-B may be formed using a transparent photosensitive resin.

The color filter layer CFL may further include a buffer layer BFL. For example, the buffer layer BFL may be a protection layer protecting the first to third filters CF-B, CF-G and CF-R. The buffer layer BFL may be an inorganic layer including at least one inorganic material among silicon nitride, silicon oxide and silicon oxynitride. The buffer layer BFL may be formed as a single layer or multiple layers.

In addition, the second filter CF-G and the third filter CF-R may be yellow filters. The second filter CF-G and the third filter CF-R may be provided in one body without distinction.

Though not shown, the color filter layer CFL may further include a light blocking part (not shown). The light blocking part may be a black matrix. The light blocking part may be formed by including an organic light blocking material or an inorganic light blocking material, including a black pigment or black dye. The light blocking part may prevent light leakage and may divide the boundaries among adjacent filters CF-B, CF-G and CF-R.

FIG. 5A and FIG. 5B are cross-sectional views showing light emitting elements ED and ED-a of embodiments. At least one among the light emitting elements ED and ED-a, explained referring to FIG. 5A and FIG. 5B may be applied to at least one among the first to third light emitting elements ED-1, ED-2 and ED-3, shown in FIG. 4 by the same manner.

Referring to FIG. 5A and FIG. 5B, the light emitting elements ED and ED-a may include a first electrode EL1, an electron transport region ETR, an emission layer EML, a hole transport region HTR, and a second electrode EL2, stacked in order. Referring to FIG. 5A, the hole transport region HTR may include a hole injection layer HIL and a hole transport layer HTL. The hole transport layer HTL may be disposed on the emission layer EML, and the hole injection layer HIL may be disposed on the hole transport layer HTL. The electron transport region ETR may include an electron transport layer ETL and an electron injection layer EIL. The electron transport layer ETL may be disposed on the electron injection layer EIL, and the emission layer EML may be disposed on the electron transport layer ETL. In the light emitting element ED, the electron transport region ETR may include the metal nanoparticles NP of an embodiment.

Compared to the light emitting element ED of FIG. 5A, the light emitting element ED-a of FIG. 5B is different in that the hole transport region HTR further includes an electron blocking layer EBL, and the electron transport region ETR further includes a hole blocking layer HBL. The electron blocking layer EBL may be disposed between the emission layer EML and the hole transport layer HTL. The hole blocking layer HBL may be disposed between the emission layer EML and the electron transport layer ETL. In addition, in the light emitting element ED-a, the hole transport region HTR and the electron transport region ETR may include the metal nanoparticles NP and NP-1 of embodiments. In another embodiment, different from the drawings, any one among the electron blocking layer EBL and the hole blocking layer HBL may be omitted.

Referring to FIG. 5A and FIG. 5B, the electron transport region ETR may include the metal nanoparticles NP of an embodiment. Particularly, the electron transport layer ETL may include the metal nanoparticles NP of an embodiment. Different from the drawings, at least one among the hole blocking layer HBL and the electron injection layer EIL may include the metal nanoparticles NP of an embodiment. Otherwise, the hole blocking layer HBL, the electron transport layer ETL and/or the electron injection layer EIL may include the metal nanoparticles NP of an embodiment. The electron transport region ETR including the metal nanoparticles NP of an embodiment may contribute to the increase of electron injection properties and/or electron transport properties and thus, to the improvement of the light efficiency of the light emitting elements ED and ED-a.

Referring to FIG. 5B, the hole transport region HTR may include the metal nanoparticles NP-1 of an embodiment. The metal nanoparticles NP-1 included in the hole transport region HTR and the metal nanoparticles NP included in the electron transport region ETR may be the same or different. That is, a material constituting the metal nanoparticles NP-1 of an embodiment and included in the hole transport region HTR and a material constituting the metal nanoparticles NP of an embodiment and included in the electron transport region ETR may be the same or different. The metal nanoparticles NP and NP-1 of embodiments will be explained in detail later.

The emission layer EML may include a quantum dot QD-C. Hereinafter, the same explanation on the first to third quantum dots QD-C1, QD-C2 and QD-C3, shown in FIG. 4 will be applied to the quantum dot QD-C.

In the description, the quantum dot QD-C means the crystal of a semiconductor compound. The quantum dot QD-C may emit light of various wavelengths according to the size of the crystal. The diameter of the quantum dot QD-C may be, for example, about 1 nanometer (nm) to about 10 nm.

The quantum dot QD-C may be synthesized by a chemical bath deposition, a metal organic chemical vapor deposition, a molecular beam epitaxy or a similar process therewith. The chemical bath deposition is a method of growing quantum dot QD-C particle crystal after mixing an organic solvent and a precursor material. During the growth of the crystal, the organic solvent naturally plays the role of a dispersant coordinated at the surface of the quantum dot QD-C crystal and may control the growth of the crystal. Accordingly, the chemical bath deposition is more favorable than a vapor deposition method such as a metal organic chemical vapor deposition (“MOCVD”) and a molecular beam epitaxy (“MBE”), and may control the growth of the quantum dot QD-C particle through a low cost process.

The quantum dot may include II-VI group semiconductor compounds, I-II-VI group semiconductor compounds, II-IV-VI group compounds, I-II-IV-VI group semiconductor compounds, III-V group semiconductor compounds, III-VI group semiconductor compounds, I-III-VI group semiconductor compounds, IV-VI group semiconductor compounds, II-IV-V group semiconductor compounds, IV group elements or compounds, and arbitrary combinations thereof. In the description, the “group” means the group in an IUPAC periodic table.

Examples of the II-VI group compound may include: a binary compound such as CdS, CdSe, CdTe, ZnS, ZnSe, ZnTe, ZnO, HgS, HgSe, HgTe, MgSe, and MgS: a ternary compound such as CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, and MgZnS: a quaternary compound such as CdZnSeS, CdZnSeTe, CdZnSTe, CdHgSeS, CdHgSeTe, CdHgSTe, HgZnSeS, HgZnSeTe, and HgZnSTe; or arbitrary combinations thereof. In another embodiment, the II-VI group semiconductor compound may further include a metal in group I and/or an element in group IV. The I-II-VI group compound may be selected from CuSnS or CuZnS, and the II-IV-VI group compound may select ZnSnS, etc. The I-II-IV-VI group compound may be selected from quaternary compounds selected from the group consisting of Cu₂ZnSnS₂, Cu₂ZnSnS₄, Cu₂ZnSnSe₄, Ag₂ZnSnS₂ and mixtures thereof.

Examples of the III-V group semiconductor compound may include: a binary compound such as GaN, GaP, GaAs, GaSb, AlN, AIP, AlAs, AlSb, InN, InP, InAs, and InSb; a ternary compound such as GaNP, GaNAs, GaNSb, GaP As, GaPSb, AlNP, AlNAs, AlNSb, AIPAs, AlPSb, InGaP, InNP, InAIP, InNAs, InNSb, InPAs, and InPSb; a quaternary compound such as GaAINP, GaAINAs, GaAINSb, GaAlPAs, GaAlPSb, GalnNP, GalnNAs, GalnNSb, GalnPAs, GalnPSb, InAINP, InAINAs, InAINSb, InAlPAs, and InAlPSb; or arbitrary combinations thereof. In another embodiment, the III-V group semiconductor compound may further include a II group element. Examples of the III-V group semiconductor compound including the element in group II may include InZnP, InGaZnP, InAlZnP, etc.

Examples of the III-VI group semiconductor compound may include: a binary compound such as GaS, Ga₂S₃, GaSe, Ga₂Se₃, GaTe, InS, InSe, In₂Se₃, and InTe: a temary compound such as InGaS₃, and InGaSe₃; or arbitrary combinations thereof.

Examples of the I-III-VI group semiconductor compound may include: a ternary compound such as AgInS, AgInS₂, AgInSe₂, AgGaS, AgGaS₂, AgGaSe₂, CuInS, CuInS₂, CuInSe₂, CuGaS₂, CuGaSe₂, CuGaO₂, AgGaO₂, and AgAlO₂; a quaternary compound such as AgInGaS₂, and CuInGaS₂; or arbitrary combinations thereof.

Examples of the IV-VI group semiconductor compound may include: a binary compound such as SnS, SnSe, SnTe, PbS, PbSe, and PbTe: a ternary compound such as SnSeS, SnSeTe, SnSTe, PbSeS, PbSeTe, PbSTe, SnPbS, SnPbSe, and SnPbTe: a quaternary compound such as SnPbSSe, SnPbSeTe, and SnPbSTe; or arbitrary combinations thereof.

Examples of the II-IV-V group semiconductor compound may be a ternary compound selected from the group consisting of ZnSnP, ZnSnP₂, ZnSnAs₂, ZnGeP₂, ZnGeAs₂, CdSnP₂, CdGeP₂ and mixtures thereof.

The IV group element or compound may include: a single element compound such as Si, and Ge: a binary compound such as SiC, and SiGe; or arbitrary combinations thereof.

Each element included in a multi-element compound such as the binary compound, the ternary compound and the quaternary compound may be present at uniform concentration or non-uniform concentration in a particle. That is, the chemical formulae mean the types of elements included in the compound, and the element ratio in the compound may be different. In an embodiment, for example, AgInGaS₂ may mean AgInₓGa₁₋ₓS₂ (x is a real number of 0 to 1).

In an embodiment, the quantum dot QD-C may have a single structure in which the concentration of each element included in the quantum dot QD-C is uniform, or a double structure of core-shell. For example, the material included in the core and the material included in the shell may be different.

The shell of the quantum dot QD-C may play the role of a protection layer for preventing the chemical deformation of the core and maintaining semiconductor properties and/or a charging layer for providing the quantum dot with electrophoresis properties. The shell may be a single layer or a multilayer. In the core/shell structure, the shell may have a concentration gradient in which the concentration of an element present in the shell is reduced toward the core.

Examples of the shell of the quantum dot QD-C may include a metal or non-metal oxide, a semiconductor compound, or combinations thereof. Examples of the metal or non-metal oxide may include: a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO: a ternary compound such as MgAl₂O₄, CoFe₂O₄, NiFe₂O₄ and CoMn₂O₄; or arbitrary combinations thereof. Examples of the semiconductor compound may include III-VI group semiconductor compounds; II-VI group semiconductor compounds; III-V group semiconductor compounds; III-VI group semiconductor compounds; I-III-VI group semiconductor compounds; IV-VI group semiconductor compounds; or arbitrary combinations thereof, as described in this description. In an embodiment, for example, the semiconductor compound may include CdS, CdSe, CdTe, ZnS, ZnSe, ZnTe, ZnSeS, ZnTeS, GaAs, GaP, GaS, GaSe, AgGaS, AgGaS₂, GaSb, HgS, HgSe, HgTe, InAs, InP, InGaP, InSb, AlAs, AIP, AlSb, etc., or arbitrary combinations thereof.

Each element included in the multi-element compound such as the binary compound, and the ternary compound may be present at uniform concentration or non-uniform concentration in a particle. That is, the chemical formulae mean the types of elements included in the compound, and the element ratio in the compound may be different.

The quantum dot QD-C may have a full width of half maximum (“FWHM”) of emission wavelength spectrum of about 45 nm or less, particularly, about 40 nm or less, more particularly, about 30 nm or less. Within this range, color purity or color reproducibility may be improved. In addition, light emitted via such quantum dot QD-C is emitted in all directions, and light view angle may be improved (i.e., a wider light view angle may be secured.).

In addition, the type of the quantum dot QD-C may particularly be spherical, pyramidal, multi-arm, or cubic nanoparticle, nanotube, nanowire, nanofiber, nanoplate particle, etc. may be used.

By controlling the size of the quantum dot QD-C or by controlling the element ratio in the compound constituting the quantum dot QD-C, energy band gap may be controlled, and various wavelength bands of light may be obtained from an emission layer EML including the quantum dot QD-C. Accordingly, by using such quantum dot QD-C (by using quantum dots having different sizes or by controlling an element ratio in a quantum dot compound differently), a light emitting element emitting various wavelengths of light may be accomplished. Particularly, the size of the quantum dot QD-C or the element ratio in the compound constituting the quantum dot QD-C may be selected to emit red, green and/or blue light. In addition, the quantum dots QD-C may be provided to combine various emission colors to emit white light.

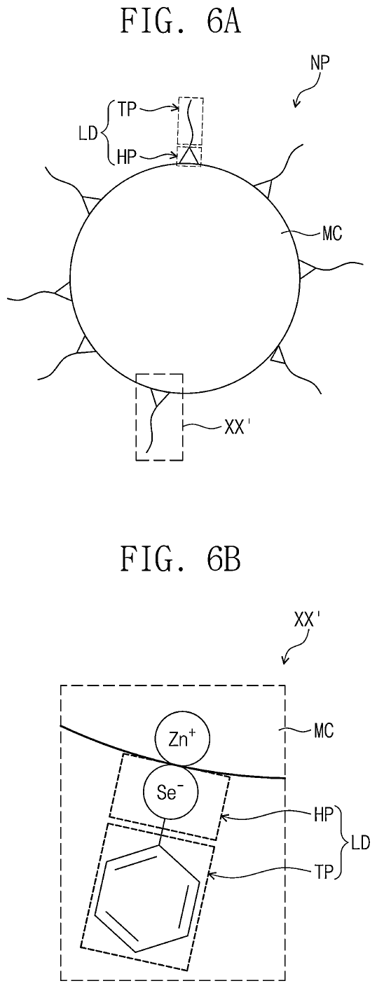

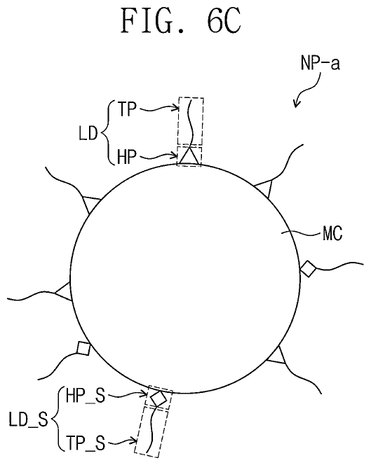

FIG. 6A is a diagram showing a metal nanoparticle of an embodiment. The metal nanoparticle NP of an embodiment may include a core MC and a ligand LD bonded to the core MC. In FIG. 6A, eight ligands LD are shown, but the number of the ligand LD is not limited thereto. Hereinafter, the same explanation on the metal nanoparticles NP and NP-1, shown in FIG. 5A and FIG. 5B may be applied to the explanation on the metal nanoparticle NP of an embodiment.

The core MC of the metal nanoparticle NP may include a metal oxide. The metal oxide may include at least one among SnO, SnO₂, CuGaO₂, Ga₂O₃, Cu₂O, SrCu₂O₂, SrTiO₃, CuAlO₂, Ta₂O₅, NiO, BaSnO₃, and TiO₂, or may be represented by Formula M-1 below:

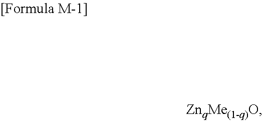

In Formula M-1, “q” may be a real number of 0 to 0.3. Me may be Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba. For example, in Formula M-1, Me may be Mg. That is, in the metal nanoparticle NP of an embodiment, the core MC may include magnesium zinc oxide. However, these are illustrations, and the material included in the core MC in the metal nanoparticle NP of an embodiment is not limited thereto.

In an embodiment, the ligand LD may include at least one among Se and Te. The conventional metal nanoparticle included a hydroxide ion, and the stability thereof with the passage of time was low, and thus, the application of an inkjet printing method or a dispensing method was unsuitable. If a metal nanoparticle including a hydroxide ion is exposed to oxygen and moisture, gelation occurs, and agglomeration occurs due to the relatively short distance among particles. Accordingly, the discharge of the metal nanoparticles including the hydroxide ions from an inkjet printing machine and a dispenser was not easy. The metal nanoparticle NP of an embodiment includes a ligand LD including at least one among Se bonded to a phenyl group and Te bonded to a phenyl group, and stability with the passage of time may be achieved. In addition, the metal nanoparticle NP of an embodiment may show excellent discharge stability.

The ligand LD may be derived from a first compound represented by the following Formula 1. The first compound may include at least one among Se and Te, and Se and Te may be bonded to a phenyl group.

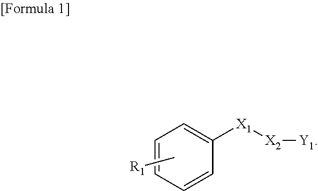

In Formula 1, X₁ may be Se or Te. X₂ may be a direct linkage, Se, or Te. Accordingly, the first compound represented by Formula 1 may include at least one among Se and Te.

Y₁ may be a hydrogen atom or a substituted or unsubstituted phenyl group. If Y₁ is a hydrogen atom, X₂ may be a direct linkage. For example, Y₁ may be a hydrogen atom, the ligand LD derived from the first compound represented by Formula 1 may include X₁⁻, because the hydrogen atom is removed, and X₁⁻ may be bonded to the core MC. X₁⁻ may be Se (Se anion) or Te (Te anion). Differently, Y₁ may be a substituted or unsubstituted phenyl group, X₂ may be a direct linkage, the ligand LD derived from the first compound represented by Formula 1 may include X₁⁻, because the substituted or unsubstituted phenyl group is removed, and X₁⁻ may be bonded to the core MC. Otherwise, Y₁ may be a substituted or unsubstituted phenyl group, X₂ may be Se or Te, the bond between X₁ and X₂ may be dissociated, and the ligand LD derived from the first compound represented by Formula 1 may include a ligand including X₁⁻, and a ligand including X₂⁻. In the ligand including X₁⁻, X₁⁻ may be bonded to the core MC, and in the ligand including X₂⁻, X₂⁻ may be bonded to the core MC. However, these are only illustrations, and an embodiment of the invention is not limited thereto.

In Formula 1, R₁ may be a hydrogen atom, a substituted or unsubstituted amine group of 1 to 10 carbon atoms, a substituted or unsubstituted alkyl group of 1 to 10 carbon atoms, or a substituted or unsubstituted alkoxy group of 1 to 10 carbon atoms. For example, R₁ may be a hydrogen atom, a methyl group, a methoxy group, or a methylamine group. However, these are illustrations, and an embodiment of the invention is not limited thereto.

In an embodiment, for example, Formula 1 may be represented by the following Formula 1-1. Formula 1-1 represents Formula 1 in which the position of R₁ is embodied.

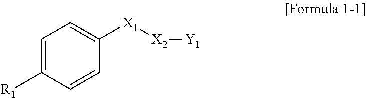

In Formula 1-1, the same contents explained in Formula 1 may be applied for X₁, X₂, Y₁, and R₁. For example, the first compound may be represented by any one among the compounds in the following Compound Group 1. However, these are illustrations, and an embodiment of the invention is not limited thereto.

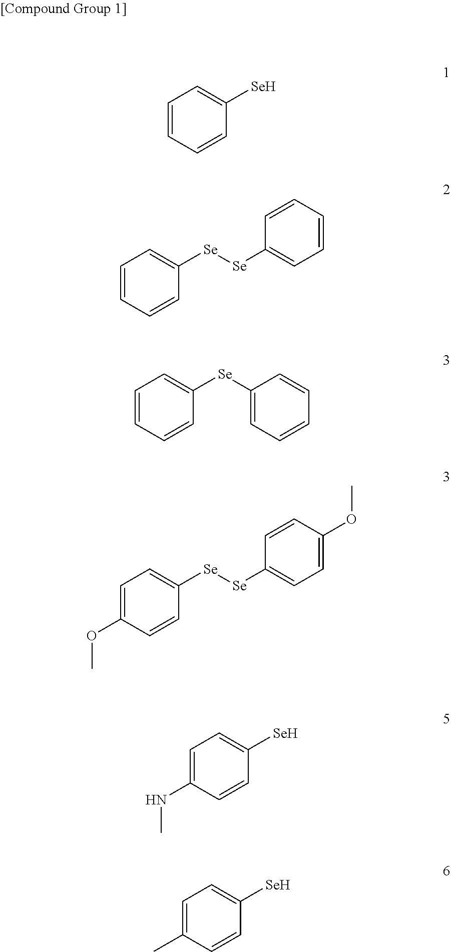

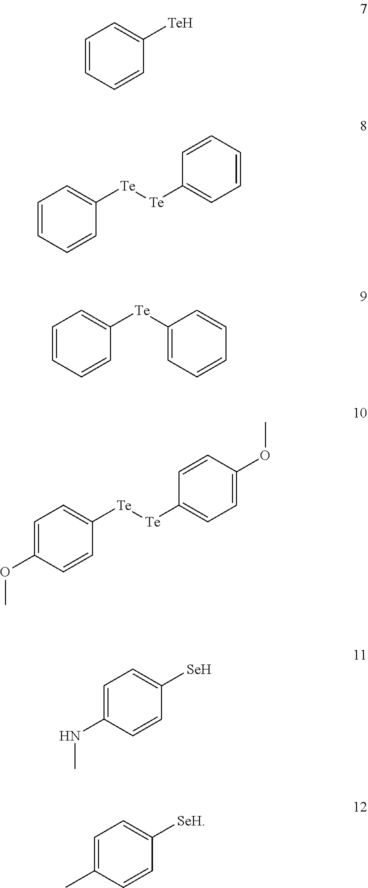

Otherwise, the ligand LD may be derived from an ion represented by Formula 2. The ion represented by the following Formula 2 may include at least one among Se⁻ and Te⁻. Se⁻ and Te⁻ may be bonded to a phenyl group:

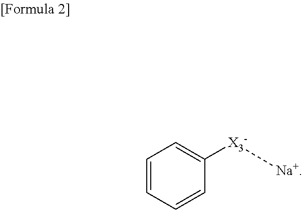

In Formula 2, X₃⁻ may be Se⁻ or Te⁻. As described above, the ligand LD including Se⁻ or Te⁻ may be bonded to the core MC. The dotted line between X₃⁻ and Na⁺ indicates ionic bonding.

In an embodiment, the surface of the metal nanoparticle NP may be modified with the ligand LD. The ligand LD may include a head part HP bonded to the surface of the metal nanoparticle NP and a tail part TP bonded to the head part HP. In the ligand LD, the head part HP may be a part directly bonded to the metal nanoparticle NP. The head part HP may include at least one among Se and Te. More particularly, the head part HP may include at least one among Se⁻ and Te⁻. The tail part TP may include a substituted or unsubstituted phenyl group.

FIG. 6B is an enlarged diagram of region XX′ in FIG. 6A. In FIG. 6B, a metal oxide constituting the core MC includes at least Zn, and the ligand LD includes Se⁻ and a phenyl group bonded to Se⁻. The head part HP of the ligand LD may include Se—, and Se⁻ may be bonded to Zn⁺ of the core MC. The tail part TP of the ligand LD may include a phenyl group. However, FIG. 6B is an illustration, and the metal oxide constituting the core MC and a material constituting the ligand LD are not limited thereto.

At the surface of the metal nanoparticle NP, the metal of the metal oxide constituting the core MC may be exposed as an ion type, and the ligand LD may be bonded to the metal ion. In the metal nanoparticle provided in a hole transport region and an electron transport region, if the ligand is not bonded to the metal ion, but the metal ion is exposed at the surface, the light efficiency of a light emitting element may be deteriorated. The exposed metal ion at the surface may be referred to as “surface defect”. That is, due to the surface defect at the metal nanoparticle, the light efficiency of a light emitting element may be deteriorated. In the metal nanoparticle NP of an embodiment, the ligand LD may be bonded to the metal ion exposed at the surface of the core MC, and the deterioration of the light efficiency of a light emitting element ED may be effectively minimized.

In an embodiment, the weight of an organic component in the metal nanoparticles NP may be about 12 weight percentages (wt %) to about 30 wt % based on the total weight of the metal nanoparticles NP. The organic component is the organic component of the surface of the metal nanoparticle NP. In an embodiment, for example, the organic component may include an organic component constituting the phenyl group. If the weight of the organic component the metal nanoparticles NP is less than about 12 wt % based on the total weight of the metal nanoparticles NP, the gelation or agglomeration of the metal nanoparticles may occur, and stability with the passage of time may be deteriorated. If the weight of the organic component the metal nanoparticles NP is greater than about 30 wt % based on the total weight of the metal nanoparticles NP, charge injection and transport properties may be deteriorated. Charges mean holes and electrons. Differently, if the weight of the organic component the metal nanoparticles NP is about 12 wt % to about 30 wt % based on the total weight of the metal nanoparticles NP, the stability of the metal nanoparticles NP with the passage of time may be maintained, and excellent charge injection and transport properties may be shown. In the description, the weight of the organic component was measured by a thermogravimetric analysis (“TGA”) method.

FIG. 6C is a diagram showing a metal nanoparticle NP-a according to another embodiment of the invention. Compared to the metal nanoparticle NP shown in FIG. 6A, the metal nanoparticle NP-a of FIG. 6C is different in including an auxiliary ligand LD_S. Hereinafter, in the explanation on FIG. 6C, the overlapping contents with those explained referring to FIG. 6B will not be explained again, and different features will be explained mainly.

In an embodiment, the metal nanoparticle NP-a may further include an auxiliary ligand LD_S bonded to the core MC. Referring to FIG. 6C, the number of the auxiliary ligand LD_S may be smaller than the number of the ligand LD. This is an illustration, and an embodiment of the invention is not limited thereto.

The auxiliary ligand LD_S may include an auxiliary head part HP_S bonded to the core MC and an auxiliary tail part TP_S bonded to the auxiliary head part HP_S. The auxiliary ligand LD_S may be derived from a second compound including ethylene glycol thiol. Particularly, the auxiliary ligand LD_S may be derived from a second compound including polyethylene glycol thiol. The auxiliary head part HP_S may be derived from the thiol group of ethylene glycol thiol.

In an embodiment, for example, the second compound may include at least one among poly(ethylene glycol) 2-mercaptoethyl ether acetic acid and thiol-PEG₂-acid(3-(2-(2-mercaptoethoxy)ethoxy)propanoic acid). The auxiliary ligand LD_S derived from the second compound including ethylene glycol thiol may improve the dispersibility of the metal nanoparticles NP-a. In the method of manufacturing the light emitting element of an embodiment, which will be explained later, the metal nanoparticles NP may be dispersed in a solvent CV (FIG. 10) and provided as a composition COP (FIG. 10). The metal nanoparticle NP-a of an embodiment may include the auxiliary ligand LD_S and may be uniformly dispersed in the solvent CV (FIG. 10).

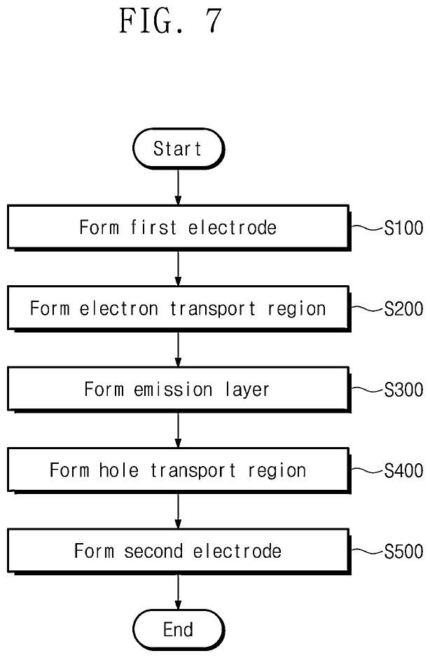

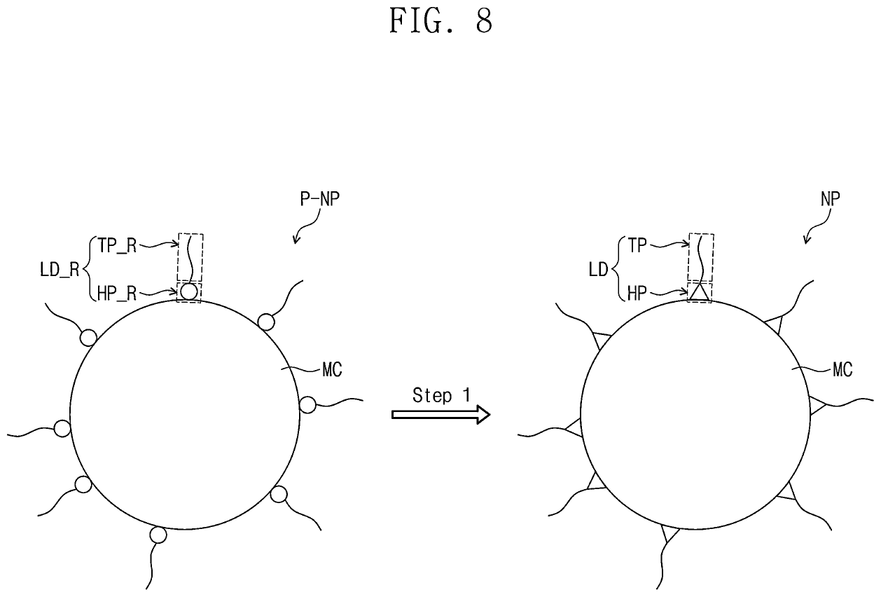

The light emitting element ED of an embodiment may be manufactured by the method for manufacturing a light emitting element of an embodiment. FIG. 7 is a flowchart showing the method for manufacturing a light emitting element of an embodiment. FIG. 8 to FIG. 10 are diagrams schematically showing the manufacturing steps of the light emitting element of an embodiment. Hereinafter, in the explanation on FIG. 7 to FIG. 10, the overlapping contents with those explained referring to FIG. 1 to FIG. 6C will not be explained again, and different features will be explained mainly.

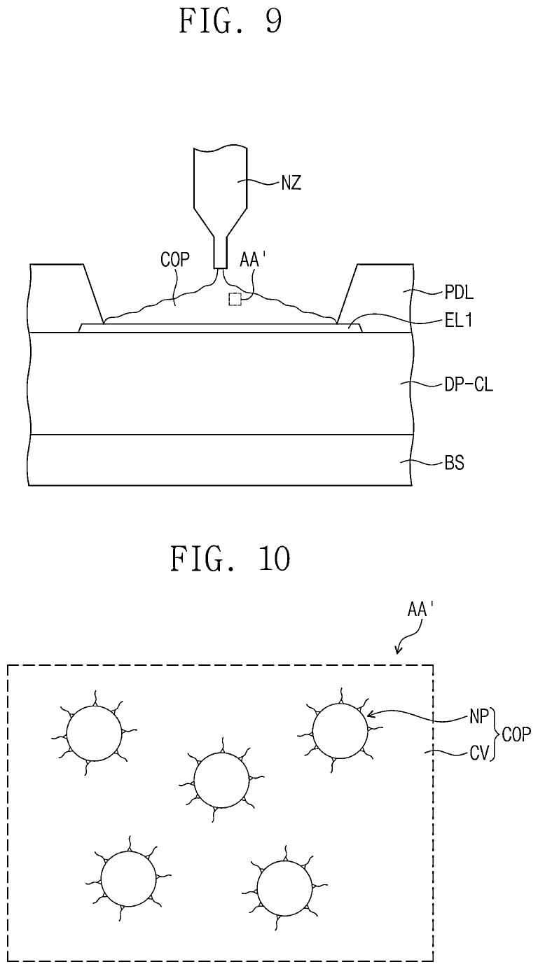

Referring to FIG. 7, the method for manufacturing a light emitting element may include a step of forming a first electrode (S100), a step of forming an electron transport region on the first electrode (S200), a step of forming an emission layer on the electron transport region (S300), a step of forming a hole transport region on the emission layer (S400), and a step of forming a second electrode on the hole transport region (S500). The first electrode EL1 may be formed on a base layer BS including a substrate. Particularly, the first electrode EL1 may be formed on a circuit layer DP-CL (FIG. 9).

The emission layer EML may be formed by providing a first composition including quantum dots QD-C (FIG. 5A and FIG. 5B). The first composition may include the quantum dots QD-C (FIG. 5A and FIG. 5B) and a solvent (not shown) in which the quantum dots QD-C (FIG. 5A and FIG. 5B) are dispersed. For example, the quantum dots QD-C (FIG. 5A and FIG. 5B) may be dispersed in an organic solvent and provided by an inkjet printing method or a dispensing method.

In the method for manufacturing a light emitting element of an embodiment, at least one among the step of forming an electron transport region (S200) and the step of forming a hole transport region (S400) may include a step of providing a second composition COP (FIG. 9) including the metal nanoparticles NP. Referring to FIG. 8, the method for manufacturing a light emitting element of an embodiment may include a step of preparing metal nanoparticles NP, prior to the step of providing the second composition COP (FIG. 9).

Metal nanoparticles NP may be prepared from preliminary metal nanoparticles P-NP. The preliminary metal nanoparticle P-NP may include a core MC and a preliminary ligand LD_R bonded to the core MC. The preliminary ligand LD_R may include a preliminary head part HP_R bonded to the core MC and a preliminary tail part TP_R bonded to the head part HP_R. The preliminary head part HP_R may include a hydroxide ion. In FIG. 8, “Step 1” represents a step of preparing a metal nanoparticle NP. Particularly, “Step 1” represents a step of preparing a metal nanoparticle NP by modifying the surface of the preliminary metal nanoparticle P-NP.

Ethanol, at least one among the above-described first compound and ion, and the preliminary metal nanoparticle P-NP may be mixed to form a mixture, and the mixture may be heated to form a ligand LD, and the ligand LD thus formed may be bonded to the core MC. As described above, the first compound may be represented by Formula 1 as described, and the ion may be represented by Formula 2 as described. In an embodiment, the ligand LD may include at least one among Se and Te.

If heat is provided to the mixture, the ligand LD may be formed from the first compound or ion, and the ligand LD may be combined with the core MC. With the provision of heat, bonds constituting the first compound may be dissociated, or deprotonation reaction may occur in the first compound. During the deprotonation reaction, hydrogen atoms may be removed as described above. The mixture may further include a material promoting the deprotonation reaction. In an embodiment, for example, the mixture may further include at least one among potassium hydroxide, sodium hydroxide, trimethylammonium hydroxide (TMAM) and tetramethylammonium hydroxide (TMAH). However, these are illustrations, and the material included in the mixture is not limited thereto.

The preliminary ligand LD_R may be removed, and the ligand LD may be bonded to the core MC to prepare the metal nanoparticle NP. In the preliminary metal nanoparticle P-NP, the preliminary ligand LD_R including a hydroxide ion may be removed. The metal nanoparticle NP including the ligand LD derived from the first compound and/or ion may maintain stability with the passage of time and show excellent charge injection and transport properties.

After preparing the metal nanoparticles NP from the preliminary metal nanoparticles P-NP, a nonpolar solvent may be provided to precipitate and separate the metal nanoparticles NP. The metal nanoparticles NP thus separated may be provided to the second composition COP. In an embodiment, for example, the nonpolar solvent may include at least one among hexane and octane. However, these are illustrations, and the nonpolar solvent used for the preparation and separation of the metal nanoparticles NP is not limited thereto.

Referring to FIG. 9, the second composition COP including the metal nanoparticles NP according to an embodiment may be provided through a nozzle NZ. The second composition COP including the metal nanoparticles NP according to an embodiment may be provided by an inkjet printing method or a dispensing method. Accordingly, a method for manufacturing a light emitting element of an embodiment, including the step of providing the second composition COP may show excellent manufacturing efficiency.

The metal nanoparticle NP according to an embodiment may include at least one among Se bonded to a phenyl group and Te bonded to a phenyl group, and may show easy discharging properties from the nozzle NZ. That is, the metal nanoparticle NP according to an embodiment includes at least one among Se bonded to a phenyl group and Te bonded to a phenyl group and may show excellent discharging properties.

FIG. 10 is an enlarged cross-sectional view of region AA′ in FIG. 9. FIG. 10 may be a diagram particularly showing the second composition COP including the metal nanoparticles NP of an embodiment. Referring to FIG. 10, the second composition COP may include the metal nanoparticles NP and a solvent CV. The metal nanoparticles NP may be dispersed in the solvent CV. As described above, the metal nanoparticle NP may further include an auxiliary ligand LD_S (FIG. 6C). Accordingly, the metal nanoparticles NP may be uniformly dispersed in the solvent CV.

Table 1 below shows evaluation results of the metal nanoparticles of the Comparative Example and the Examples. In the metal nanoparticle of the Comparative Example and the metal nanoparticles of the Examples, there are differences only in the ligands, and the cores include the same metal oxide. The particle size was obtained by measuring the size of the metal nanoparticles and was measured by a dynamic light scattering method. In the metal nanoparticles, the weights of organic components were measured by a thermogravimetric analysis method. The metal nanoparticle of the Comparative Example includes a hydroxide ion as the ligand.

In Table 1, PL_QY (%, defect emission) is the emission efficiency in visible light wavelength region, generated according to the surface defects of the metal nanoparticles, and the greater the PL_QY is, the greater the surface defects are. In the metal nanoparticles, if the surface defects increase, the light efficiency of a light emitting element including metal nanoparticles in a hole transport region and/or electron transport region may be deteriorated. First excitonic absorption peak is the wavelength showing the highest absorbance on the light absorption spectrum of the metal nanoparticles.

The first compounds provided during forming the ligand included in the metal nanoparticles of embodiments are shown below. The metal nanoparticles of Examples 1 to 5 are metal nanoparticles according to embodiments, and include at least one among Se bonded to a phenyl group and Te bonded to a phenyl group. Se or Te included in the first compound is combined with the surface of the metal nanoparticles. In Compounds 2, 8 and 10 below, a bond between Se—Se or Te—Te is dissociated, and Se or Te is combined with the surface of the metal nanoparticle.

### First Compound Used in the Examples

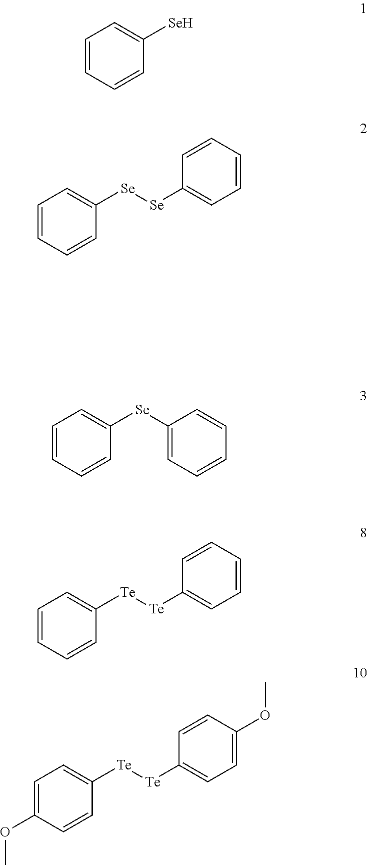

TABLE 1

| | | | First | | | |
|---|---|---|---|---|---|---|
| | | | excitonic | Particle | Particle | Weight of |
| | Ligand | PL_QY | absorption | size | size | organic |
| | (or first | (%, defect | peak | (after | (after | component |
| | compound) | emission) | (nm) | 0 days) | 7 days) | (wt %) |
| Comparative | Hydroxide | 48 | 315 | 10.9 | 50.2 | 11.2 |
| Example | ion | | | | | |
| Example 1 | Compound 1 | 12 | 315 | 10.9 | 11.0 | 16.2 |
| Example 2 | Compound 2 | 30 | 314 | 12.6 | 13.1 | 17.4 |
| Example 3 | Compound 3 | 25 | 314 | 10.6 | 12.0 | 15.3 |
| Example 4 | Compound 8 | 32 | 315 | 10.8 | 11.5 | 16.8 |
| Example 5 | Compound 10 | 30 | 314 | 11.2 | 12.0 | 16.5 |

Referring to Table 1, compared to the metal nanoparticles of the Comparative Example, it can be found that the metal nanoparticles of Examples 1 to 5 showed reduced light emission depending on the surface defects. That is, the metal nanoparticles of Examples 1 to 5 include small surface defects, and it is considered that light emitting elements including the metal nanoparticles of Examples 1 to 5 showed excellent light efficiency.

It can be found that the metal nanoparticles of Examples 1 to 5 had the weight of the organic component of about 12 wt % to about 30 wt % based on a total weight of the metal nanoparticles. If comparing after 3 days with after 7 days, the metal nanoparticles of Examples 1 to 5 were found to keep the similar levels of particle sizes. Differently, the particle size of the metal nanoparticles of the Comparative Example increased by about four times or more after 7 days. The increase of the particle size of the metal nanoparticles of the Comparative Example according to the passage of time is due to the agglomeration reaction and gelation of the particles. In addition, it was confirmed that the metal nanoparticles of the Comparative Example underwent the agglomeration reaction and gelation, and the transparency of the dispersing solvent was deteriorated. It can be found that the metal nanoparticles of Examples 1 to 5 did not undergo the agglomeration reaction and gelation of the particles, and excellent stability with the passage of time was shown. Accordingly, the metal nanoparticles of an embodiment was found suitable for an inkjet printing method or a dispensing method.

Meanwhile, it can be found that the metal nanoparticles of the Comparative Example and Examples 1 to 5 showed similar first excitonic absorption peak values. Through this, it can be confirmed that the metal nanoparticles of the Comparative Example and Examples 1 to 5 showed the similar level of light absorbance.

The light emitting element of an embodiment may include an electron transport region, an emission layer including a quantum dot, and a hole transport region. At least one among the electron transport region and the hole transport region may include the metal nanoparticle of an embodiment, and the metal nanoparticle of an embodiment may include a core including a metal oxide and a ligand bonded to the core. The ligand may include at least one among Se bonded to a phenyl group and Te bonded to a phenyl group, and may show excellent charge injection and transport properties. Accordingly, a display device including the light emitting element of an embodiment may show excellent light efficiency.

In addition, the method for manufacturing a light emitting element of an embodiment may include a step of providing metal nanoparticles including a ligand in at least one among a step of forming an electron transport region and a step of forming a hole transport region. The ligand may include at least one among Se bonded to a phenyl group and Te bonded to a phenyl group, and may show excellent stability with the passage of time and discharging stability. Accordingly, the metal nanoparticles including the ligand may be provided by an inkjet printing method or a dispensing method.

The light emitting element and the display device including the light emitting device of an embodiment include metal nanoparticles in which a ligand is bonded to a core, and may show excellent light efficiency.

The method for manufacturing a light emitting element of an embodiment includes a step of providing a composition including metal nanoparticles in which a ligand is bonded and may show excellent manufacturing efficiency.

Although the embodiments of the present invention have been described, it is understood that the present invention should not be limited to these embodiments, but various changes and modifications can be made by one ordinary skilled in the art within the spirit and scope of the present invention as hereinafter claimed.

What is claimed is:

1. A light emitting element, comprising:
a first electrode;
an electron transport region disposed on the first electrode;
an emission layer disposed on the electron transport region and comprising quantum dots;
a hole transport region disposed on the emission layer; and
a second electrode disposed on the hole transport region,
wherein
at least one among the electron transport region and the hole transport region comprises a metal nanoparticle, and
the metal nanoparticle comprises:
a core comprising a metal oxide; and
a ligand bonded to the core, the ligand comprising at least one among Selenium (Se) and Tellurium (Te), and the ligand being derived from a first compound represented by following Formula 1 or an ion represented by following Formula 2: 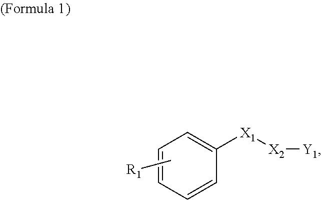
in Formula 1,
X₁ is Se or Te,
X₂ is a direct linkage, Se, or Te,
Y₁ is a hydrogen atom or a substituted or unsubstituted phenyl group, where, if Y₁ is a hydrogen atom, X₂ is a direct linkage, and
R₁ is a hydrogen atom, a substituted or unsubstituted amine group of 1 to 10 carbon atoms, a substituted or unsubstituted alkyl group of 1 to 10 carbon atoms, or a substituted or unsubstituted alkoxy group of 1 to 10 carbon atoms, 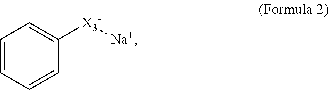
in Formula 2,
X₃⁻ is Se⁻ or Te⁻.

2. The light emitting element of claim 1, wherein at least one among Se and Te comprised in the ligand is bonded to a surface of the core.

3. The light emitting element of claim 2, wherein the ligand comprises a head part bonded to the surface and comprising at least one among Se and Te, and a tail part bonded to the head part and comprising a substituted or unsubstituted phenyl group.

4. The light emitting element of claim 1, wherein the first compound is represented by any one among compounds in following Compound Group 1:

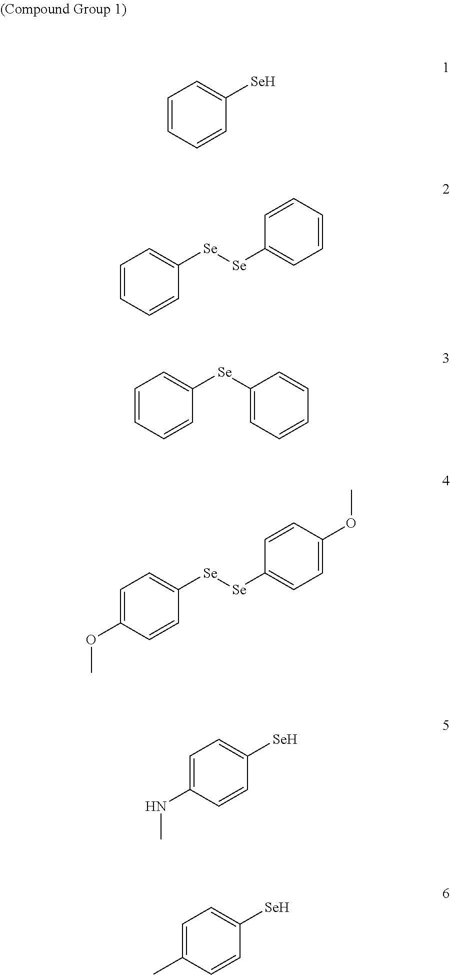

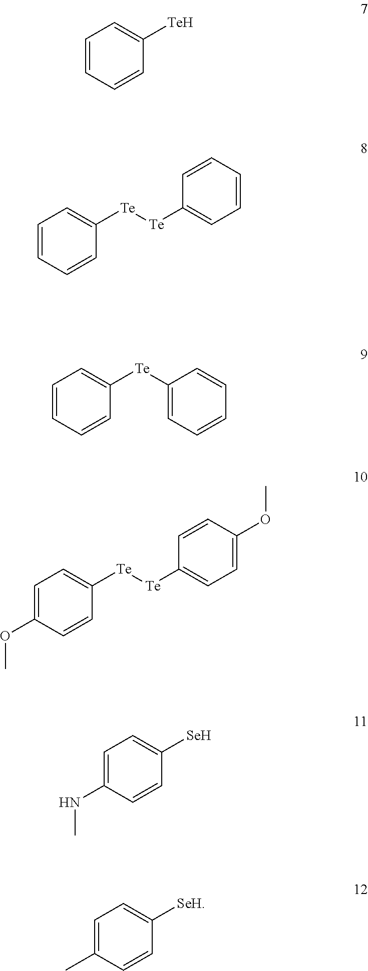

5. The light emitting element of claim 1, wherein the metal nanoparticle further comprises an auxiliary ligand bonded to the core, and
the auxiliary ligand is derived from a second compound comprising ethylene glycol thiol.

6. The light emitting element of claim 5, wherein the second compound comprises at least one among poly(ethylene glycol) 2-merchaptoethyl ether acetic acid and 3-(2-(2-mercaptoethoxy)ethoxy)propanoic acid (thiol-PEG₂-acid).

7. The light emitting element of claim 1, wherein the metal oxide comprises at least one among SnO, SnO₂, CuGaO₂, Ga₂O₃, Cu₂O, SrCu₂O₂, SrTiO₃, CuAlO₂, Ta₂O₅, NiO, BaSnO₃, and TiO₂, or is represented by following Formula M-1: 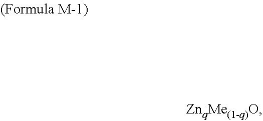
in Formula M-1,
“q” is 0 to 0.3, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

8. The light emitting element of claim 1, wherein a weight of an organic component in the metal nanoparticle is about 12 wt % to about 30 wt % based on a total weight of the metal nanoparticle.

9. The light emitting element of claim 1, wherein the electron transport region comprises an electron injection layer disposed on the first electrode, an electron transport layer disposed on the electron injection layer, and a hole blocking layer disposed on the electron transport layer, and
at least one among the electron injection layer, the electron transport layer, and the hole blocking layer comprises the metal nanoparticle.

10. The light emitting element of claim 1, wherein the hole transport region comprises an electron blocking layer disposed on the emission layer, a hole transport layer disposed on the electron blocking layer, and a hole injection layer disposed on the hole transport layer, and
at least one among the electron blocking layer, the hole transport layer, and the hole injection layer comprises the meal nanoparticle.

11. A method for manufacturing a light emitting element, the method comprising:
forming a first electrode on a substrate;
forming an electron transport region on the first electrode;
providing quantum dots on the electron transport region to form an emission layer;
forming a hole transport region on the emission layer; and
forming a second electrode on the hole transport region,
wherein
at least one among the forming of the electron transport region and the forming of the hole transport region comprises providing a composition comprising a metal nanoparticle, and
the metal nanoparticle comprises:
a core comprising a metal oxide; and
a ligand bonded to the core, the ligand comprising at least one among Se and Te, and the ligand being derived from a first compound represented by following Formula 1 or an ion represented by following Formula 2: 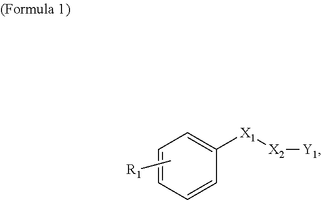
in Formula 1,
X₁ is Se or Te,
X₂ is a direct linkage, Se, or Te,
Y₁ is a hydrogen atom or a substituted or unsubstituted phenyl group, where, if Y₁ is a hydrogen atom, X₂ is a direct linkage, and
R₁ is a hydrogen atom, a substituted or unsubstituted amine group of 1 to 10 carbon atoms, a substituted or unsubstituted alkyl group of 1 to 10 carbon atoms, or a substituted or unsubstituted alkoxy group of 1 to 10 carbon atoms, 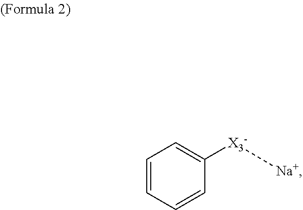
in Formula 2,
X₃⁻ is Se⁻ or Te⁻.

12. The method for manufacturing the light emitting element of claim 11, wherein the composition is provided by an inkjet printing method or a dispensing method.

13. The method for manufacturing the light emitting element of claim 11, further comprising preparing the metal nanoparticle prior to providing the composition, wherein the preparing of the metal nanoparticle comprises:
preparing a preliminary metal nanoparticle comprising the core and a preliminary ligand bonded to the core; and
heating a mixture comprising the preliminary metal nanoparticle and at least one among the first compound and the ion.

14. The method for manufacturing the light emitting element of claim 13, wherein, during the heating of the mixture, the preliminary ligand is removed, and the ligand is bonded to the core.

15. The method for manufacturing the light emitting element of claim 13, wherein the mixture further comprises at least one among potassium hydroxide, sodium hydroxide, trimethylammonium hydroxide (TMAM), and tetramethylammonium hydroxide (TMAH).

16. The method for manufacturing the light emitting element of claim 11, wherein at least one among Se and Te comprised in the ligand is bonded to a surface of the core.

17. The method for manufacturing the light emitting element of claim 11, wherein the first compound is represented by any one among compounds in following Compound Group 1:

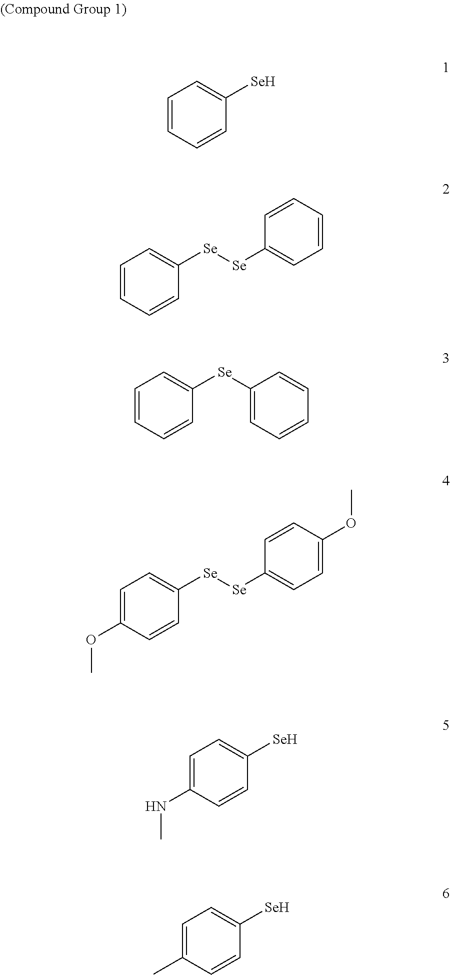

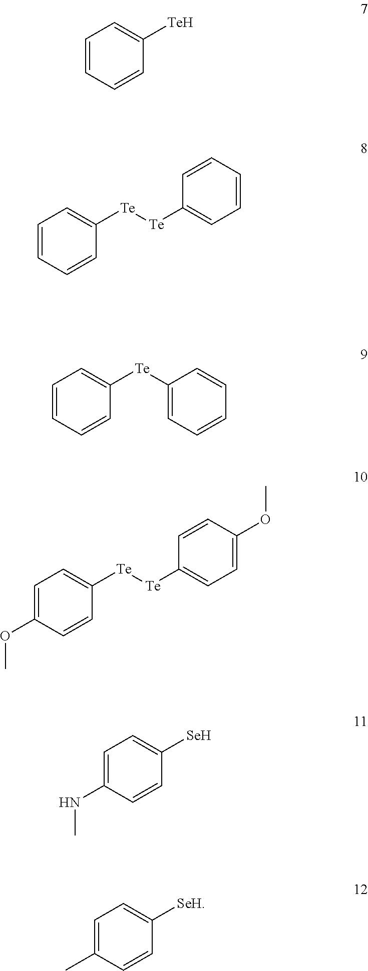

18. The method for manufacturing the light emitting element of claim 11, wherein the metal nanoparticle further comprises an auxiliary ligand bonded to the core, and
the auxiliary ligand is derived from a second compound comprising ethylene glycol thiol.

19. The method for manufacturing the light emitting element of claim 11, wherein the metal oxide comprises at least one among SnO, SnO₂, CuGaO₂, Ga₂O₃, Cu₂O, SrCu₂O₂, SrTiO₃, CuAlO₂, Ta₂O₅, NiO, BaSnO₃, and TiO₂, or is represented by following Formula M-1: 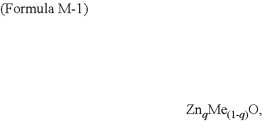
in Formula M-1,
“q” is 0 to 0.3, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba.

20. The method for manufacturing the light emitting element of claim 11, wherein a weight of an organic component in the metal nanoparticle is about 12 wt % to about 30 wt % based on a total weight of the metal nanoparticle.

21. A display device comprising:
a circuit layer; and
a display element layer comprising a pixel definition layer disposed on the circuit layer, a pixel opening being defined in the pixel definition layer, and a light emitting element,
wherein
the light emitting element comprises:
a first electrode exposed at the pixel opening;
an electron transport region disposed on the first electrode;
an emission layer disposed on the electron transport region and comprising quantum dots;
a hole transport region disposed on the emission layer; and
a second electrode disposed on the hole transport region,
wherein at least one among the electron transport region and the hole transport region comprises a metal nanoparticle,
wherein the metal nanoparticle comprises:
a core comprising a metal oxide; and
a ligand bonded to the core, the ligand comprising at least one among Se and Te, and the ligand being derived from a first compound represented by following Formula 1 or an ion represented by following Formula 2: 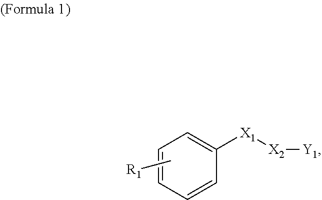
in Formula 1,
X₁ is Se or Te,
X₂ is a direct linkage, Se, or Te,
Y₁ is a hydrogen atom or a substituted or unsubstituted phenyl group, where, if Y₁ is a hydrogen atom, X₂ is a direct linkage, and
R₁ is a hydrogen atom, a substituted or unsubstituted amine group of 1 to 10 carbon atoms, a substituted or unsubstituted alkyl group of 1 to 10 carbon atoms, or a substituted or unsubstituted alkoxy group of 1 to 10 carbon atoms, 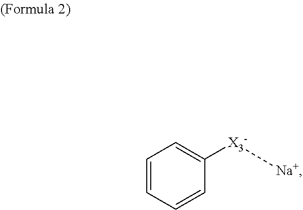
in Formula 2,
X₃⁻ is Se⁻ or Te⁻.

22. The display device of claim 21, wherein at least one among Se and Te, comprised in the ligand is bonded to a surface of the core.

23. The display device of claim 21, wherein the first compound is represented by any one among compounds in following Compound Group 1:

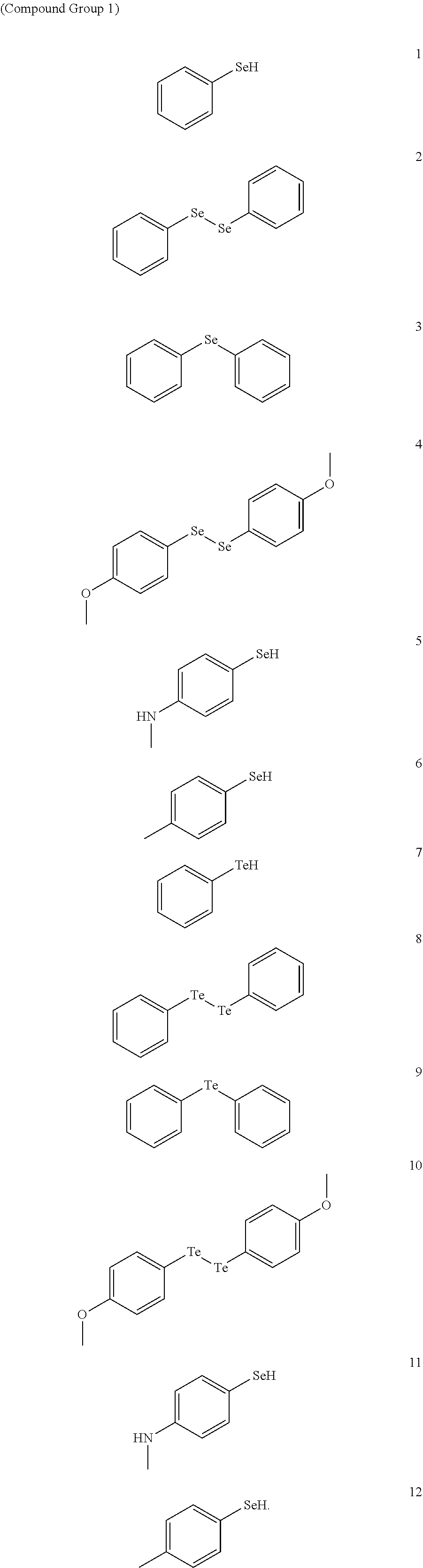

24. The display device of claim 21, wherein the metal nanoparticle further comprises an auxiliary ligand bonded to the core, and
the auxiliary ligand is derived from a second compound comprising ethylene glycol thiol.

25. The display device of claim 21, wherein the metal oxide comprises at least one among SnO, SnO₂, CuGaO₂, Ga₂O₃, CuzO, SrCu₂O₂, SrTiO₃, CuAlO₂, Ta₂O₅, NiO, BaSnO₃, and TiO₂, or is represented by following Formula M-1: 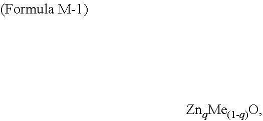
in Formula M-1,
“q” is 0 to 0.3, and
Me is Li, Be, Na, Mg, Al, K, Ca, Ti, V, Cr, Mn, Fe, Co, Ni, Cu, Ga, Ge, Rb, Sr, Zr, Nb, Mo, Ru, Pd, Ag, In, Sn(II), Sn(IV), Sb, or Ba
